(19) United States
(12) Patent Application Publication
(10) Pub. No.: US 2026/0268974 A1
(43) Pub. Date: Sep. 10, 2026

(54) DATA LATCH CIRCUIT AND SEMICONDUCTOR DEVICE

(71) Applicant: Kioxia Corporation, Tokyo (JP)

(72) Inventor: Hiromitsu KOMAI, Kamakura (JP)

(73) Assignee: Kioxia Corporation, Tokyo (JP)

(21) Appl. No.: 19/236,161

(22) Filed: Jun. 12, 2025

(30) Foreign Application Priority Data
Mar. 7, 2025 (JP) 2025-036322

(51) Int. Cl. G11C 16/08; G11C 16/04; G11C 16/10; G11C 16/26; H03K 19/173

(52) U.S. Cl. CPC G11C 16/08; G11C 16/0483; G11C 16/10; G11C 16/26; H03K 19/1735

(57) ABSTRACT

A data latch circuit includes a first transistor, a second transistor, a third transistor, a fourth transistor and a fifth transistor. The second transistor has its current path connected at one end to a first potential node having a first potential, and connected at another end to the first node. The fifth transistor has its current path connected at one end to a second node, and connected at another end to a second potential node. When the second transistor is off, a leakage current corresponding to a potential difference between the first potential node and the first node occurs in the second transistor. When the fifth transistor is off, a leakage current corresponding to a potential difference between the second node and the second potential node occurs in the fifth transistor.

### CROSS-REFERENCE TO RELATED APPLICATION

This application is based upon and claims the benefit of priority from the prior Japanese Patent Applications No. 2025-036322, filed on Mar. 7, 2025, the entire contents of which are incorporated herein by reference.

### FIELD

An embodiment described herein generally relates to a data latch circuit and a semiconductor device.

### BACKGROUND

NAND and other data latch circuits used for semiconductor devices are known.

### BRIEF DESCRIPTION OF THE DRAWINGS

FIG. 1 is a block diagram showing a schematic configuration of a memory system according to an embodiment;

FIG. 2 is a block diagram showing a schematic configuration of a semiconductor storage device according to the embodiment;

FIG. 3 is a circuit diagram showing a configuration of a semiconductor storage device according to the embodiment;

FIG. 4 is a sectional view showing a sectional structure of the semiconductor storage device according to the embodiment;

FIG. 5 is a block diagram showing a schematic configuration of a sense amplifier unit according to the embodiment;

FIG. 6 is a block diagram showing schematic configurations of a sense amplifier and an input-output circuit according to the embodiment;

FIG. 7 is a circuit diagram showing a configuration of a data latch circuit XDL according to the embodiment;

FIG. 8 is a circuit diagram showing an operation example of the data latch circuit XDL according to the embodiment;

FIG. 9 is a circuit diagram showing an operation example of the data latch circuit XDL according to the embodiment;

FIG. 10 is a circuit diagram showing an operation example of the data latch circuit XDL according to the embodiment;

FIG. 11 is a circuit diagram showing an operation example of the data latch circuit XDL according to the embodiment;

FIG. 12 is a circuit diagram showing an operation example of the data latch circuit XDL according to the embodiment;

FIG. 13 is a circuit diagram showing an operation example of the data latch circuit XDL according to the embodiment;

FIG. 14 is a circuit diagram showing a configuration of a data latch circuit SDL according to the embodiment;

FIG. 15 is a sectional view showing a sectional structure of the semiconductor storage device according to the embodiment;

FIG. 16 is a circuit diagram showing an operation example of the data latch circuit SDL according to the embodiment;

FIG. 17 is a circuit diagram showing an operation example of the data latch circuit SDL according to the embodiment;

FIG. 18 is a circuit diagram showing an operation example of the data latch circuit SDL according to the embodiment;

FIG. 19 is a circuit diagram showing an operation example of the data latch circuit SDL according to the embodiment;

FIG. 20 is a circuit diagram showing an operation example of the data latch circuit SDL according to the embodiment;

FIG. 21 is a circuit diagram showing another configuration of the data latch circuit SDL according to the embodiment;

FIG. 22 is a circuit diagram showing a configuration of a data latch circuit SDL according to a second modification of the embodiment;

FIG. 23 is a circuit diagram showing an operation example of the data latch circuit SDL according to the second modification of the embodiment;

FIG. 24 is a circuit diagram showing an operation example of the data latch circuit SDL according to the second modification of the embodiment;

FIG. 25 is a circuit diagram showing an operation example of the data latch circuit SDL according to the second modification of the embodiment; and

FIG. 26 is a circuit diagram showing an operation example of the data latch circuit SDL according to the second modification of the embodiment.

### DETAILED DESCRIPTION

In general, according to the embodiment, a data latch circuit includes a first transistor, a second transistor, a third transistor, a fourth transistor and a fifth transistor. The first transistor is configured such that one end of a current path is connected to a first node and another end of the current path is connected to a first bus. The second transistor is configured such that one end of a current path is connected to a first potential node having a first potential and another end of the current path is connected to the first node. The third transistor is configured such that one end of a current path is connected to the first node, another end of the current path is connected to a second potential node having a second potential lower than the first potential, and a gate is connected to a second node. The fourth transistor is configured such that one end of a current path is connected to a first potential node, another end of the current path is connected to the second node, and a gate is connected to the first node. The fifth transistor is configured such that one end of a current path is connected to the second node and another end of the current path is connected to the second potential node. When the second transistor is off, a leakage current corresponding to a potential difference between the first potential node and the first node will occur in the second transistor. When the fifth transistor is off, a leakage current corresponding to a potential difference between the second node and the second potential node will occur in the fifth transistor.

An embodiment will be described below with reference to the accompanying drawings. To facilitate understanding of the description, the same components in different drawings are denoted by the same reference signs whenever possible and redundant description thereof will be omitted.

### 1 Embodiment

The semiconductor storage device according to the embodiment will be described. The semiconductor storage device according to the present embodiment is a nonvolatile storage device configured as a NAND flash memory.

### 1.1 Configuration of Memory System

First, a configuration of a memory system according to the present embodiment will be described.

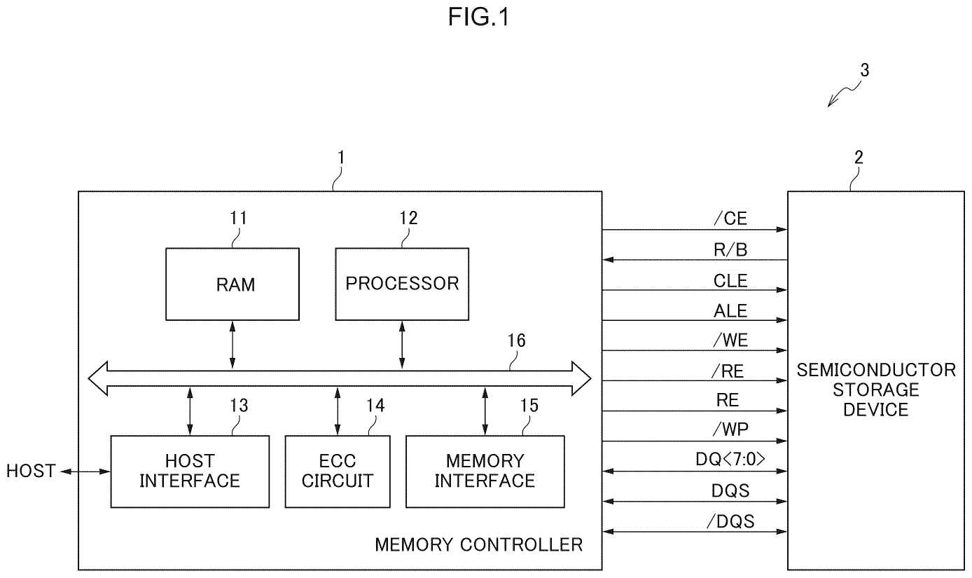

As shown in FIG. 1, the memory system 3 according to the present embodiment includes a memory controller 1 and a semiconductor storage device 2. The memory system 3 is connectable to a host. The host is an electronic device such as a personal computer or a portable terminal.

The memory controller 1 controls writing of data into the semiconductor storage device 2 in response to a write request from the host. The memory controller 1 also controls reading of data from the semiconductor storage device 2 in response to a read request from the host.

Signals are exchanged between the memory controller 1 and the semiconductor storage device 2, including: a chip enable signal /CE, a ready/busy signal R/B, a command latch enable signal CLE, an address latch enable signal ALE, a write enable signal /WE, read enable signals/RE and RE, a write protect signal /WP, a signal DQ<7:0>, and data strobe signals DQS and /DQS.

The chip enable signal /CE is transmitted from the memory controller 1 to the semiconductor storage device 2. The chip enable signal /CE is intended to enable the semiconductor storage device 2. The ready/busy signal R/B is transmitted from the semiconductor storage device 2 to the memory controller 1. The ready/busy signal R/B is intended to indicate whether the semiconductor storage device 2 is in a ready state or in a busy state. The “ready state” is a state in which instructions are accepted from outside, for example. The “busy state” is a state in which instructions are not accepted from outside, for example.

The command latch enable signal CLE is transmitted from the memory controller 1 to the semiconductor storage device 2. The command latch enable signal CLE is intended to indicate that the signal DQ<7:0> is a command. The address latch enable signal ALE is transmitted from the memory controller 1 to the semiconductor storage device 2. The address latch enable signal ALE is intended to indicate that the signal DQ<7:0> is an address. The write enable signal /WE is transmitted from the memory controller 1 to the semiconductor storage device 2. The write enable signal /WE is intended to take a received signal into the semiconductor storage device 2 and is asserted each time the memory controller 1 receives a command, an address, and data. The memory controller 1 instructs the semiconductor storage device 2 to take in the signal DQ<7:0> while the write enable signal /WE is at logic low.

The read enable signal /RE is transmitted from the memory controller 1 to the semiconductor storage device 2. The signal RE is a complementary signal of the signal /RE. The read enable signals /RE and RE are intended for the memory controller 1 to read data from the semiconductor storage device 2. The read enable signals /RE and RE are used to control operation timing of the semiconductor storage device 2 during output, for example, of the signal DQ<7:0>. The signal DQ<7:0> is a substance of data exchanged between the semiconductor storage device 2 and the memory controller 1, and includes a command, an address, and data. The data strobe signal DQS is a timing control signal exchanged between the semiconductor storage device 2 and the memory controller 1 together with the signal DQ<7:0>. The signal /DQS is a complementary signal of the signal DQS. The data strobe signals DQS and /DQS are intended to control input-output timing of the signal DQ<7:0>.

The memory controller 1 includes a RAM 11, a processor 12, a host interface 13, an ECC circuit 14, and a memory interface 15, which are interconnected via an internal bus 16.

The host interface 13 outputs a request received from the host, user data (write data), and the like to the internal bus 16. The host interface 13 is a circuit that transmits user data read out of the semiconductor storage device 2, a response from the processor 12, and the like to the host. As the host interface 13, for example, SCSI, SAS (Serial Attached SCSI), ATA, SATA (Serial ATA), PCIe (PCI Express), Ethernet (registered trademark), Fibre Channel, and NVMe (NVM Express) (registered trademark) can be used.

The memory interface 15 is a circuit that controls the process of writing user data and the like into the semiconductor storage device 2 and the process of reading user data and the like from the semiconductor storage device 2 on instructions from the processor 12. Communication between the memory interface 15 and the semiconductor storage device 2 conforms, for example, to SDR (single data rate) interface, toggle DDR (double data rate) interface, or ONFI (Open NAND flash interface) standard.

The processor 12 exerts overall control over the memory controller 1. The processor 12 is a CPU, an MPU, or the like. When a request is received from the host via the host interface 13, the processor 12 performs control according to the request. For example, in response to the request from the host, the processor 12 instructs the memory interface 15 to write user data and parity into the semiconductor storage device 2. In response to the request from the host, the processor 12 also instructs the memory interface 15 to read the user data and parity from the semiconductor storage device 2.

The processor 12 determines a storage area (memory area) on the semiconductor storage device 2 for the user data accumulated in the RAM 11. The user data is stored in the RAM 11 via the internal bus 16. The processor 12 determines the memory areas for data (page data) managed in the unit of writing, i.e., on a page-by-page basis. Hereinafter, the user data stored on one page of the semiconductor storage device 2 will also be referred to as “unit data.” Generally, the unit data is encoded, and stored as code words in the semiconductor storage device 2. According to the present embodiment, encoding is not essential. The memory controller 1 may store the unit data in the semiconductor storage device 2 without encoding, but FIG. 1 shows as an example a configuration in which encoding is done.

The processor 12 determines a memory area of the semiconductor storage device 2 at the write destination for each unit data item. Physical addresses have been assigned to the memory areas of the semiconductor storage device 2. The processor 12 manages the memory areas at the write destinations for unit data using the physical addresses. By specifying determined memory areas (physical addresses), the processor 12 instructs the memory interface 15 to write user data into the semiconductor storage device 2. The processor 12 manages correspondence between logical addresses (the logical addresses managed by the host) and the physical addresses of the user data. When a read request containing a logical address from the host is received, the processor 12 identifies the physical address corresponding to the logical address and instructs the memory interface 15 to read the user data, by specifying the physical address.

The ECC circuit 14 encodes the user data stored in the RAM 11, and thereby generates code words. The ECC circuit 14 also decodes the code words read out of the semiconductor storage device 2.

The RAM 11 temporarily stores the user data received from the host, before storing the user data in the semiconductor storage device 2 and temporarily stores the data read out of the semiconductor storage device 2, before transmitting the data to the host. The RAM 11 is a general-purpose memory such as a SRAM or a DRAM.

FIG. 1 shows a configuration example in which the memory controller 1 includes the ECC circuit 14 and the memory interface 15. However, the ECC circuit 14 may be incorporated in the memory interface 15. Alternatively, the ECC circuit 14 may be incorporated in the semiconductor storage device 2. Specific configurations and arrangements of the components shown in FIG. 1 are not particularly limited.

When a write request is received from the host, the memory system 3 in FIG. 1 operates as follows. The processor 12 temporarily stores the write data in the RAM 11. The processor 12 reads the data stored in the RAM 11 and inputs the data to the ECC circuit 14. The ECC circuit 14 encodes the input data and inputs code words to the memory interface 15. The memory interface 15 writes the input code words in the semiconductor storage device 2.

When a read request is received from the host, the memory system 3 in FIG. 1 operates as follows. The memory interface 15 inputs the code words read out of the semiconductor storage device 2 to the ECC circuit 14. The ECC circuit 14 decodes the input code words and stores the resulting data in the RAM 11. The processor 12 transmits the data stored in the RAM 11 to the host via the host interface 13.

### 1.2 Schematic Configuration of Semiconductor Storage Device

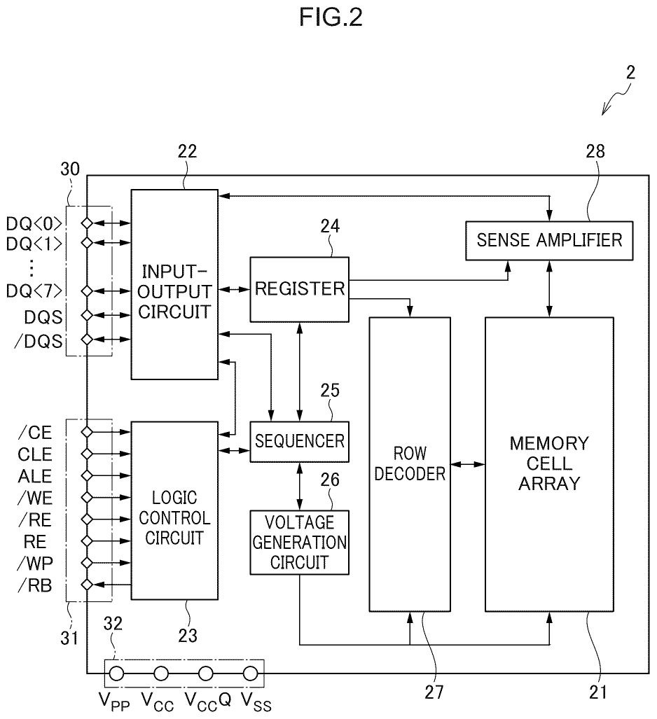

As shown in FIG. 2, the semiconductor storage device 2 includes a memory cell array 21, an input-output circuit 22, a logic control circuit 23, a register 24, a sequencer 25, a voltage generation circuit 26, a row decoder 27, a sense amplifier 28, an input/output pad group 30, a logic control pad group 31, and a power input terminal group 32.

The memory cell array 21 is a part configured to store data. The memory cell array 21 includes a plurality of memory cell transistors linked to a plurality of bit lines and a plurality of word lines.

The input-output circuit 22 exchanges the signal DQ<7:0> and the data strobe signals DQS and /DQS with the memory controller 1. Also, the input-output circuit 22 transfers a command and an address in the signal DQ<7:0> to the register 24. Furthermore, the input-output circuit 22 exchanges write data and read data with the sense amplifier 28. Communication between the input-output circuit 22 and the memory controller 1 conforms, for example, to SDR (single data rate) interface, toggle DDR (double data rate) interface, or ONFI (Open NAND flash interface) standard.

The logic control circuit 23 receives the chip enable signal /CE, the command latch enable signal CLE, the address latch enable signal ALE, the write enable signal /WE, the read enable signals RE and /RE, and the write protect signal /WP from the memory controller 1. The logic control circuit 23 transfers the ready/busy signal/RB to the memory controller 1 and informs the outside about the state of the semiconductor storage device 2.

The register 24 temporarily stores various types of data. For example, the register 24 holds commands for use to instruct write operations, read operations, erase operations, and other operations to be performed. The commands are inputted to the input-output circuit 22 from the memory controller 1, and then transferred from the input-output circuit 22 to the register 24 and held there. The register 24 also holds addresses corresponding to the commands. The addresses are inputted to the input-output circuit 22 from the memory controller 1, and then transferred from the input-output circuit 22 to the register 24 and held there. Furthermore, the register 24 also holds status information that represents the operating state of the semiconductor storage device 2. The status information is updated by the sequencer 25 as needed according to the operating states of the memory cell array 21 and the like. The status information is outputted as status signals from the input-output circuit 22 to the memory controller 1 in response to requests from the memory controller 1.

The sequencer 25 controls operations of various parts including the memory cell array 21 based on control signals inputted to the input-output circuit 22 and the logic control circuit 23 from the memory controller 1. According to the present embodiment, the sequencer 25 is an example of a control unit.

The voltage generation circuit 26 is a part configured to generate respective voltages necessary for the data write operation, data read operation, and data erase operation of the memory cell array 21. The voltages include voltages and the like applied, for example, to respective ones of a plurality of word lines and plurality of bit lines of the memory cell array 21. The operation of the voltage generation circuit 26 is controlled by the sequencer 25.

The row decoder 27 is a circuit made up of a switch group for use to apply voltages to each of the plurality of word lines of the memory cell array 21. The row decoder 27 receives a block address and a row address from the register 24 and selects a block based on the block address and selects a word line based on the row address. The row decoder 27 switches the open/closed states of the switch group such that voltages will be supplied to the selected word lines from the voltage generation circuit 26. The operation of the row decoder 27 is controlled by the sequencer 25.

The sense amplifier 28 is a circuit intended to adjust the voltage applied to the bit lines of the memory cell array 21 as well as to read the voltages of the bit lines and convert the voltages into data. During a data read, the sense amplifier 28 acquires data read to the bit lines from the memory cell transistors of the memory cell array 21 and transfers the acquired read data to the input-output circuit 22. During a data write, the sense amplifier 28 transfers the data written via the bit lines to the memory cell transistors. The operation of the sense amplifier 28 is controlled by the sequencer 25.

The input/output pad group 30 is made up of a plurality of terminals (pads) for use to exchange various signals between the memory controller 1 and the input-output circuit 22. The terminals are provided individually for the signal DQ<7:0> and the data strobe signals DQS and /DQS.

The logic control pad group 31 is made up of a plurality of terminals for use to exchange various signals between the memory controller 1 and the logic control circuit 23. The terminals are provided individually for the chip enable signal /CE, the command latch enable signal CLE, the address latch enable signal ALE, the write enable signal /WE, the read enable signals RE and /RE, the write protect signal /WP, and the ready/busy signal/RB.

The power input terminal group 32 is made up of a plurality of terminals through which various voltages necessary for operations of the semiconductor storage device 2 are applied. The voltages applied to the respective terminals include power supply voltages Vcc, VccQ, and Vpp and a ground voltage Vss. The power supply voltage Vcc is a circuit power supply voltage provided externally as an operating power supply voltage and is, for example, around 2.5 V. The power supply voltage Vcc is used to generate, for example, a voltage Vdd, which is an internal supply voltage of the semiconductor storage device 2. The power supply voltage Vdd is, for example, around 1.5 V. The power supply voltage VccQ is lower than the power supply voltage Vcc, and is, for example, 1.2 V. The power supply voltage VccQ is an input-output power supply voltage used in exchanging signals between the memory controller 1 and the semiconductor storage device 2. The power supply voltage Vpp is higher than the power supply voltage Vcc and is, for example, 12 V.

### 1.3 Circuit Configurations of Memory Cell Arrays

Next, circuit configurations of the memory cell array 21 will be described.

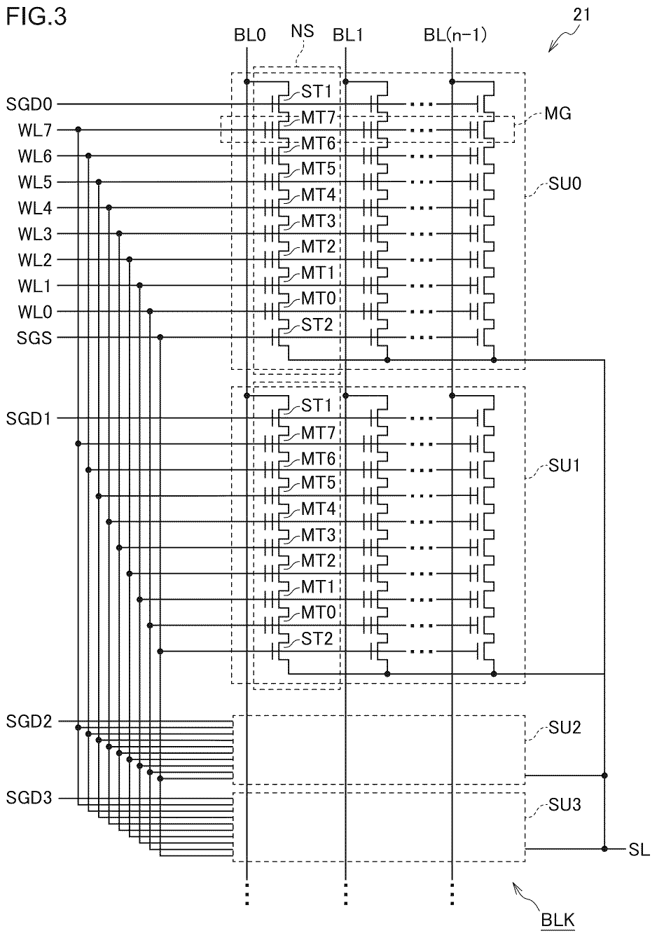

As shown in FIG. 3, the memory cell array 21 is made up of a plurality of blocks BLK. In FIG. 3, only one of the plurality of blocks BLK is illustrated. The other blocks BLK of the memory cell array 21 are similar in configuration to the block BLK shown in FIG. 3.

As shown in FIG. 3, the block BLK includes, for example, four string units SU (SU0 to SU3). Each of the string units SU includes a plurality of NAND strings NS. Each of the NAND strings NS includes, for example, eight memory cell transistors MT (MT0 to MT7) and selection transistors ST1 and ST2.

The memory cell transistors MT are placed, being connected in series between the selection transistor ST1 and the selection transistor ST2. The memory cell transistor MT7 at one end is connected to a source of the selection transistor ST1, and the memory cell transistor MT0 at the other end is connected to a drain of the selection transistor ST2.

Gates of the selection transistors ST1 in the respective string units SU0 to SU3 are commonly connected to respective select gate lines SGD0 to SGD3. Gates of the selection transistors ST2 are commonly connected to the same select gate line SGS among a plurality of string units SU in the same block BLK. Gates of the memory cell transistors MT0 to MT7 in the same block BLK are commonly connected to respective word lines WL0 to WL7. That is, the word lines WL0 to WL7 and the select gate line SGS are common among the plurality of string units SU0 to SU3 in the same block BLK, but the select gate lines SGD are provided individually for each of the string units SU0 to SU3 even in the same block BLK.

Bit lines BL (BL0, BL1, . . . , BL(n-1)), n in number, are provided in the memory cell array 21, where “n” is an integer corresponding to the number of NAND strings NS included in one string units SU0. A drain of each selection transistor ST1 in the NAND strings NS is connected to a corresponding bit line BL. A source of each selection transistor ST2 in the NAND strings NS is connected to a source line SL. The source line SL is common to the sources of a plurality of the selection transistors ST2 in the block BLK.

Data stored in a plurality of the memory cell transistors MT in the same block BLK is erased in batches. On the other hand, data reads and data writes are performed in batches with respect to a plurality of the memory cell transistors MT that are connected to one word line WL and belong to one string unit SU.

Each of the memory cell transistors MT can store three-bit data made up of, for example, a high-order bit, a middle-order bit, and a low-order bit. That is, as a method of writing data into the memory cell transistor MT, the semiconductor storage device 2 according to the present embodiment adopts a TLC system that can allow three bits of data to be stored in a single memory cell transistor MT. As a method of writing data into the memory cell transistor MT, instead of such a form, it is possible to adopt a system such as an MLC system that allows two bits of data to be stored in a single memory cell transistor MT or an SLC system that allows one bit of data to be stored in a single memory cell transistor MT.

Hereinafter, a set of one-bit data stored in a plurality of the memory cell transistors MT connected to one word line WL and belonging to one string unit SU will be referred to as a “page.” In FIG. 3, one of sets of a plurality of memory cell transistors MT such as described above is marked with the reference sign “MG.”

When three bits of data are stored in a single memory cell transistor MT as with the present embodiment, a set of a plurality of memory cell transistors MT connected to a word line WL common in one string unit SU can store three pages of data.

### 1.4 Sectional Structure of Semiconductor Storage Device

Next, the memory cell array 21 and a structure therearound will be described.

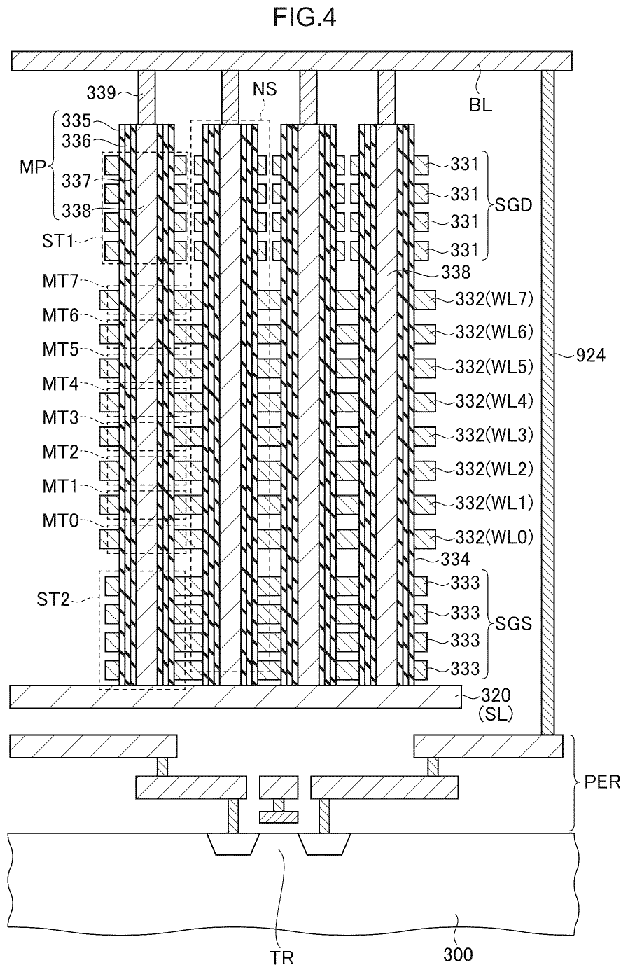

As shown in FIG. 4, in the memory cell array 21, a plurality of NAND strings NS are formed on a conductor layer 320. The conductor layer 320 is also referred to as a buried source line (BSL) and corresponds to the source line SL shown in FIG. 3.

A plurality of interconnect layers 333 functioning as the select gate line SGS, a plurality of interconnect layers 332 functioning as word lines WL, and a plurality of interconnect layers 331 functioning as a select gate line SGD are stacked above the conductor layer 320. Non-illustrated insulating layers are placed among the stacked interconnect layers 333, 332, and 331.

A plurality of memory holes 334 are formed in the memory cell array 21. The memory holes 334 penetrate vertically through the interconnect layers 333, 332, and 331 and through the non-illustrated insulating layers placed among the interconnect layers, reaching the conductor layer 320. A block insulator 335, a charge storage layer 336, and a gate insulator 337 are formed on a side face of each memory hole 334 in sequence, and moreover a conductor pillar 338 is embedded on the inner side thereof. The conductor pillar 338 is made, for example, of polysilicon, and functions as a region in which channels are formed during operation of the memory cell transistors MT and selection transistors ST1 and ST2 included in the NAND string NS. Hereinafter, a columnar body made up of the block insulator 335, the charge storage layer 336, the gate insulator 337, and the conductor pillar 338 on the inner side of each memory hole 334 will also be referred to as a memory pillar MP.

Of the memory pillar MP, parts intersecting the stacked interconnect layers 333, 332, and 331, respectively, function as transistors. Of the plurality of transistors, those located at intersections with the interconnect layers 331 function as the selection transistors ST1. Of the plurality of transistors, those located at intersections with the interconnect layers 332 function as the memory cell transistors MT (MT0 to MT7). Of the plurality of transistors, those located at intersections with the interconnect layers 333 function as the selection transistors ST2. Thanks to this configuration, the memory pillars MP function as the NAND strings NS shown in FIG. 3. The conductor pillars 338 located on the inner side of the memory pillars MP function as channels of the memory cell transistors MT or selection transistors ST1 and ST2.

An interconnect layer functioning as a bit line BL is formed above the conductor pillars 338. Contact plugs 339 connecting the conductor pillars 338 with the bit line BL are formed on upper ends of the conductor pillars 338.

A plurality of structures with a configuration similar to the one shown in FIG. 4 are arranged in the direction away from the viewer in FIG. 4. A set of the plurality of NAND strings NS lined up in the direction away from the viewer in FIG. 4 makes up one string unit SU.

In the semiconductor storage device 2 according to the present embodiment, peripheral circuitry PER is provided below the memory cell array 21, i.e., in a location between the memory cell array 21 and a semiconductor substrate 300. The peripheral circuitry PER is provided to implement data write, data read, data erase, and other operations in the memory cell array 21. The peripheral circuitry PER includes the sense amplifier 28, the row decoder 27, the voltage generation circuit 26, and the like shown in FIG. 2. The peripheral circuitry PER includes various types of transistors, RC circuits, and the like. In the example shown in FIG. 4, transistors TR formed on the semiconductor substrate 300 and the bit line BL located above the memory cell array 21 are electrically connected with each other via a contact 924.

### 1.5 Configuration of Sense Amplifier

Next, a configuration of the sense amplifier 28 will be described.

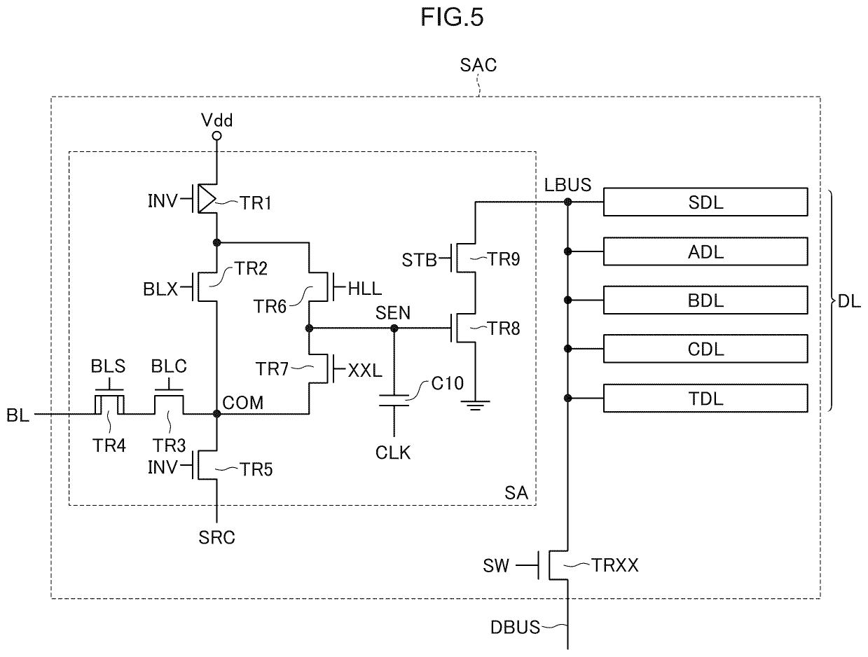

The sense amplifier 28 includes m sense amplifier circuits linked respectively to m bit lines BL. FIG. 5 shows a circuit configuration of one of m sense amplifier circuits SAC.

As shown in FIG. 5, the sense amplifier circuit SAC includes a sense amplification part SA and data latch circuits SDL, ADL, BDL, CDL, and TDL. The sense amplification part SA is connected with the data latch circuits SDL, ADL, BDL, CDL, and TDL via a bus LBUS to allow data to be exchanged therebetween. More particularly, the data latch circuits SDL, ADL, BDL, CDL, and TDL are commonly connected via the bus LBUS. The bus LBUS is connected to a bus DBUS via a transistor TRXX. A control signal SW is inputted to a gate of the transistor TRXX. The control signal SW is generated, for example, by the sequencer 25.

The sense amplification part SA senses data read to a corresponding bit line BL, for example, in a read operation and determines whether the read data is “0” or “1.” The sense amplification part SA includes transistors TR1 to TR9 and a capacitor C10, where the transistor TR1 is, for example, a p-channel MOS transistor and the transistors TR2 to TR9 are n-channel MOS transistors.

The transistor TR1 is connected to a power line at one end and to the transistor TR2 at another end. A gate of the transistor TR1 is connected to a node INV in the data latch circuit SDL. The transistor TR2 is connected to the transistor TR1 at one end, and to a node COM at another end. A control signal BLX is inputted to a gate of the transistor TR2. The transistor TR3 is connected to the node COM at one end, and to the transistor TR4 at another end. A control signal BLC is inputted to a gate of the transistor TR3. The transistor TR4 is a high-voltage MOS transistor. The transistor TR4 is connected to the transistor TR3 at one end, and to a corresponding bit line BL at another end. A control signal BLS is inputted to a gate of the transistor TR4.

The transistor TR5 is connected to the node COM at one end, and to a node SRC at another end. A gate of the transistor TR5 is connected to the node INV. The transistor TR6 is connected between the transistor TR1 and the transistor TR2 at one end, and to a node SEN at another end. A control signal HLL is inputted to a gate of the transistor TR6. The transistor TR7 is connected to the node SEN at one end, and to the node COM at another end. A control signal XXL is inputted to a gate of the transistor TR7.

The transistor TR8 is grounded at one end, and is connected to the transistor TR9 at another end. A gate of the transistor TR8 is connected to the node SEN. The transistor TR9 is connected to the transistor TR8 at one end, and to the bus LBUS at another end. A control signal STB is inputted to a gate of the transistor TR9. The capacitor C10 is connected to the node SEN at one end, and a clock CLK is inputted to the capacitor C10 at another end.

The control signals BLX, BLC, BLS, HLL, XXL, and STB are generated, for example, by the sequencer 25. For example, the voltage Vdd, which is the internal supply voltage of the semiconductor storage device 2, is applied to the power line connected to one end of the transistor TR1, and, for example, the voltage Vss, which is the ground voltage Vss of the semiconductor storage device 2, is applied the node SRC.

The data latch circuits SDL, ADL, BDL, CDL, and TDL temporarily hold read data. The data latch circuits SDL, ADL, BDL, CDL, and TDL are identical in circuit configuration, and thus, will hereinafter also be referred to collectively as the “data latch circuits DL.” Note that the data latch circuits SDL, ADL, BDL, CDL, and TDL may differ in circuit configuration from one another.

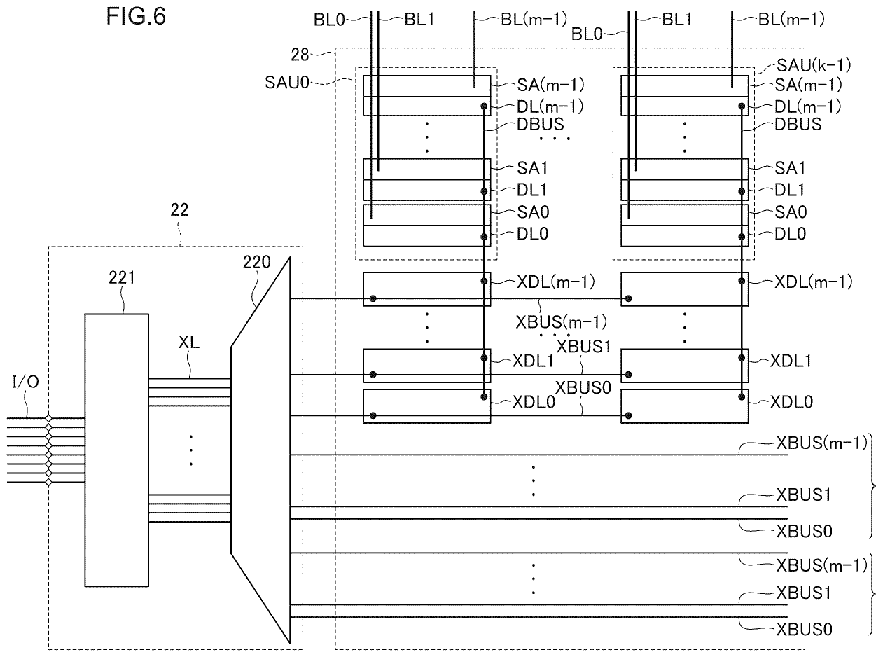

As shown in FIG. 6, the sense amplifier 28 includes k sense amplifier units SAU (SAU0 to SAU(k-1)). Each sense amplifier unit SAU includes m sense amplification parts SA (SA0 to SA(m-1)) and m data latch circuits DL (DL0 to DL(m-1)). Here, “m” and “k” are integers, which satisfy “m×k =n.” For example, “m” is 16 (2 to the fourth power) and “k” is 8192 (2 to the thirteenth power).

The m data latch circuits DL (DL0 to DL(m-1)) are connected to m data latch circuits XDL (XDL0 to XDL(m-1)) via the bus DBUS. The m data latch circuits XDL0 to XDL(m-1) are connected to the input-output circuit 22 via m buses XBUS (XBUS0 to XBUS(m-1)). The m buses XBUS0 to XBUS(m-1) are provided commonly to a plurality of (e.g., 32 to 64) sense amplifier units SAU. To put it another way, the m buses XBUS0 to XBUS(m-1) are connected with the plurality of (e.g., 32 to 64) sense amplifier units SAU. The plurality of sense amplifier units SAU are connected to the input-output circuit 22 via the buses XBUS0 to XBUS(m-1). In this way, the plurality of sense amplifier units SAU are connected to a set of the buses XBUS0 to XBUS(m-1), and multiple sets of the buses XBUS0 to XBUS(m-1) are connected to the input-output circuit 22. The data latch circuits XDL are used for data input and output between the sense amplifier units SAU and the input-output circuit 22.

The input-output circuit 22 includes a data conversion unit 220 and an input-output control unit 221. The data conversion unit 220 and the input-output control unit 221 are interconnected via a plurality of lines XL.

The data conversion unit 220 functions as a serializer during a read operation, thereby converts parallel data transmitted from the data latch circuits XDL0 to XDL(m-1) via the buses XBUS0 to XBUS(m-1) into serial signals, and transmits the serial signals to the input-output control unit 221 via the plurality of lines XL. During a read operation, the data conversion unit 220 functions as a deserializer, thereby converts the serial signals transmitted from the input-output control unit 221 via the plurality of lines XL into parallel data, and transmits the parallel data to the corresponding buses XBUS0 to XBUS(m-1).

The input-output control unit 221 is a part that controls transmission of serial signals between a plurality of input/output lines I/O and the plurality of lines XL.

### 1.6 Configuration of Data Latch Circuit XDL

Next, a configuration of the data latch circuit XDL will be described.

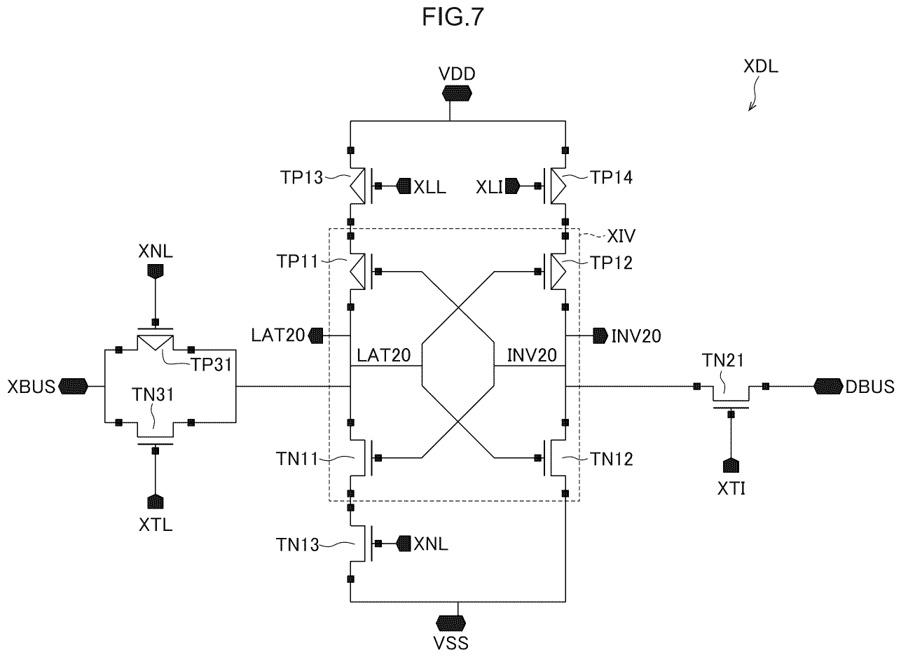

As shown in FIG. 7, each of the data latch circuits XDL includes p-channel MOS transistors TP11 to TP14 and TP31 as well as n-channel MOS transistors TN11 to TN13, TN21, and TN31.

The transistors TP11, TP12, TN11, and TN12 make up a cross-connected inverter circuit XIV. The transistors TP11 and TN11 make up a first inverter circuit, being connected in series at a node LAT20. Gates of the transistors TP11 and TN11 are both connected to a node INV20. The node LAT20 and the node INV20 function as input and output of the first inverter circuit, respectively. The transistors TP12 and TN12 make up a second inverter circuit, being connected in series at the node INV20. Gates of the transistors TP12 and TN12 are both connected to the node LAT20. The node LAT20 and the node INV20 function as input and output of the second inverter circuit, respectively.

A drain of the transistor TP11 is connected to the node LAT20 and a source of the transistor TP11 is connected to a power supply potential node VDD via the transistor TP13. The power supply potential node VDD is supplied with the power supply voltage Vdd. A control signal XLL generated by the sequencer 25 is inputted to a gate of the transistor TP13. The transistor TP13 functions as a switching element that turns on and off based on the control signal XLL.

A drain of the transistor TP12 is connected to the node INV20, and a source of the transistor TP12 is connected to the power supply potential node VDD via the transistor TP14. A control signal XLI generated by the sequencer 25 is inputted to a gate of the transistor TP14. The transistor TP12 functions as a switching element that turns on and off based on the control signal XLI.

A drain of the transistor TN11 is connected to the node LAT20 and a source of the transistor TN11 is connected to a ground potential node VSS via the transistor TN13. The ground potential node VSS is supplied with the ground voltage Vss. A control signal XNL generated by the sequencer 25 is inputted to a gate of the transistor TN13. The transistor TN13 functions as a switching element that turns on and off based on the control signal XNL.

A drain of the transistor TN12 is connected to the node INV20, and a source of the transistor TN12 is connected to the ground potential node VSS.

A drain of the transistor TN21 is connected to the bus DBUS and a source of the transistor TN21 is connected to the node INV20. A control signal XTI generated by the sequencer 25 is inputted to a gate of the transistor TN21. The transistor TN21 functions as a switching element that turns on and off based on the control signal XTI.

The transistors TP31 and TN31 are connected in parallel between the bus XBUS and the node LAT20. The control signal XNL generated by the sequencer 25 is inputted to a gate of the transistor TP31. A control signal XTL generated by the sequencer 25 is inputted to a gate of the transistor TN31. The transistors TP31 and TN31 function as switching elements that turn on and off based on the control signals XNL and XTL.

### 1.7 Operation Examples of Data Latch Circuit XDL

Next, operation examples of the data latch circuit XDL will be described.

### 1.7.1 Data Retention

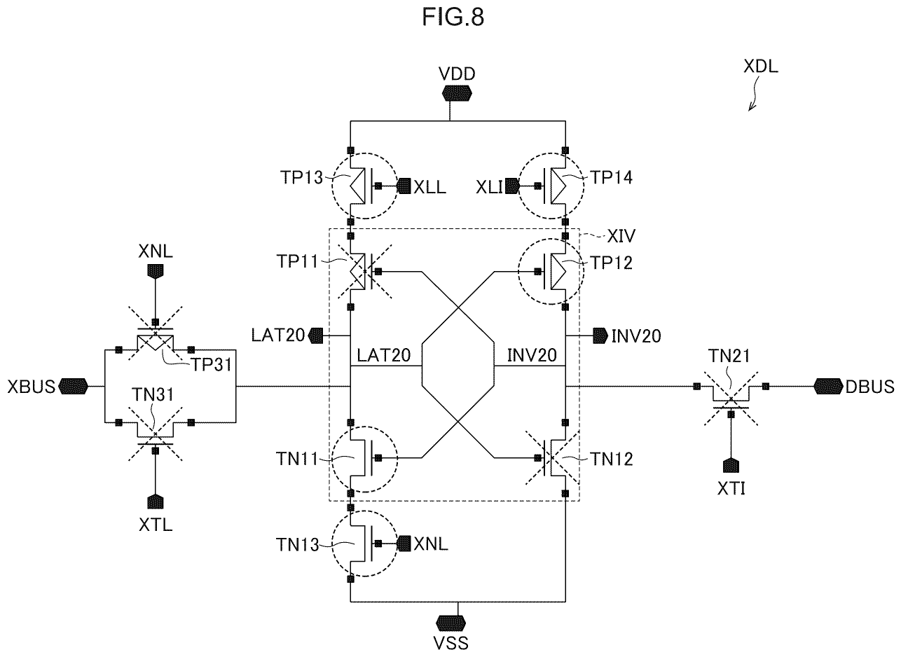

When holding data in the data latch circuit XDL, the sequencer 25 causes the data latch circuit XDL to operate as shown in FIG. 8. The sequencer 25 keeps the control signals XTL, XTI, XLI, and XLL to logic low and keeps the control signal XNL to logic high. The logic high level is set to a potential high enough to turn off p-channel MOS transistors and turn on n-channel MOS transistors, for example, to a potential corresponding to the power supply voltage Vdd. The logic low level is set to a potential low enough to turn on p-channel MOS transistors and turn on n-channel MOS transistors for example, to a potential corresponding to the ground voltage Vss.

As the respective potentials of the control signals XNL, XTL, XTI, XLI, and XLL are kept at the levels described above, the transistors TP13, TP14, and TN13 turn on while the transistors TN21, TP31, and TN31 turn off as shown in FIG. 8. In FIG. 8, the transistors remaining on are marked by a broken-line circle while the transistors remaining off are marked by a broken-line cross. Hereinafter the on and off states of transistors will be indicated in a similar manner in figures.

Due to the on/off states of the transistors, both the nodes LAT20 and INV20 are cut off from both the buses DBUS and XBUS. On the other hand, since the cross-connected inverter circuit XIV is connected to the power supply potential node VDD and the ground potential node VSS, the respective potentials of the nodes LAT20 and INV20 are maintained.

For example, if the data to be held in the node LAT20 is logic low data, the transistor TP12 turns on while the transistor TN12 turns off as shown in FIG. 8. Consequently, the node INV20 is connected to the power supply potential node VDD via the transistors TP12 and TP14, and thus the potential of the node INV20 is kept to a potential corresponding to the power supply voltage Vdd. As the potential of the node INV20 is kept to a potential corresponding to the power supply voltage Vdd, the transistor TP11 is kept off and the transistor TN11 is kept on. As a result, the node LAT20 is connected to the ground potential node VSS via the transistors TN11 and TN13, thereby keeping the potential of the node LAT20 to a potential corresponding to the ground voltage Vss.

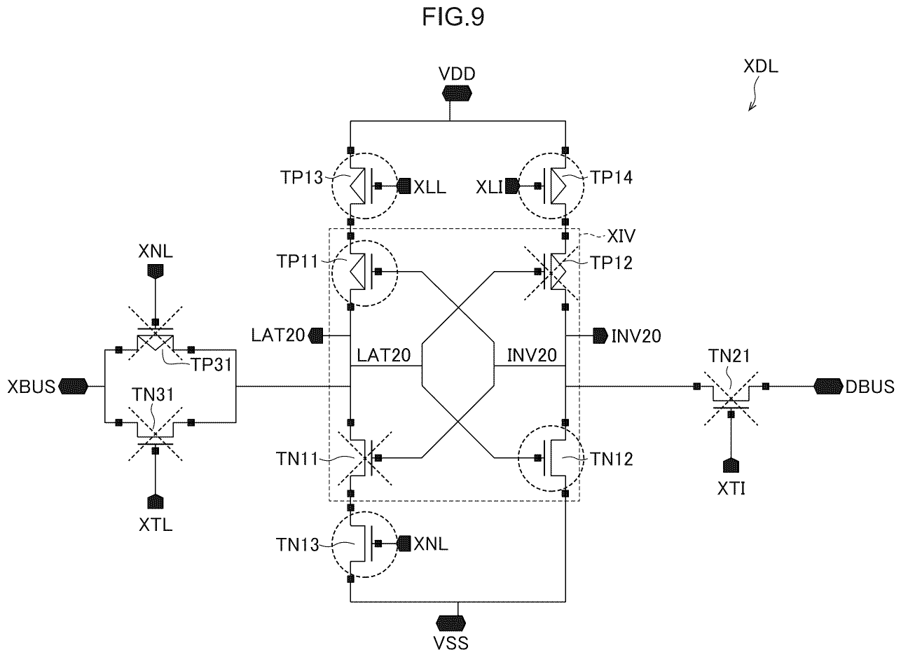

If the data to be held in the node LAT20 is logic high data, the transistor TP12 is turned off and the transistor TN12 is turned on as shown in FIG. 9. The node INV20 is connected to the ground potential node VSS via the transistor TN12, thereby keeping the potential of the node INV20 to a potential corresponding to the ground voltage Vss. As the potential of the node INV20 is kept to a potential corresponding to the ground voltage Vss, the transistor TP11 is kept on and the transistor TN11 is kept off. As a result, the node LAT20 is connected to the power supply potential node VDD via the transistors TP11 and TP13, thereby keeping the potential of the node LAT20 to a potential corresponding to the power supply voltage Vdd.

### 1.7.2 Data Input from Bus DBUS

When transferring data from the bus DBUS to the data latch circuit XDL, the sequencer 25 sets the control signal SW shown in FIG. 5 to logic high, thereby turning on the transistor TRXX. Therefore, the bus DBUS already has a potential that is based on data to be transferred to the data latch circuit XDL. If the data to be transferred is logic high, the potential of the bus DBUS has been set logic high. On the other hand, if the data to be transferred is logic low, the potential of the bus DBUS has been set logic low.

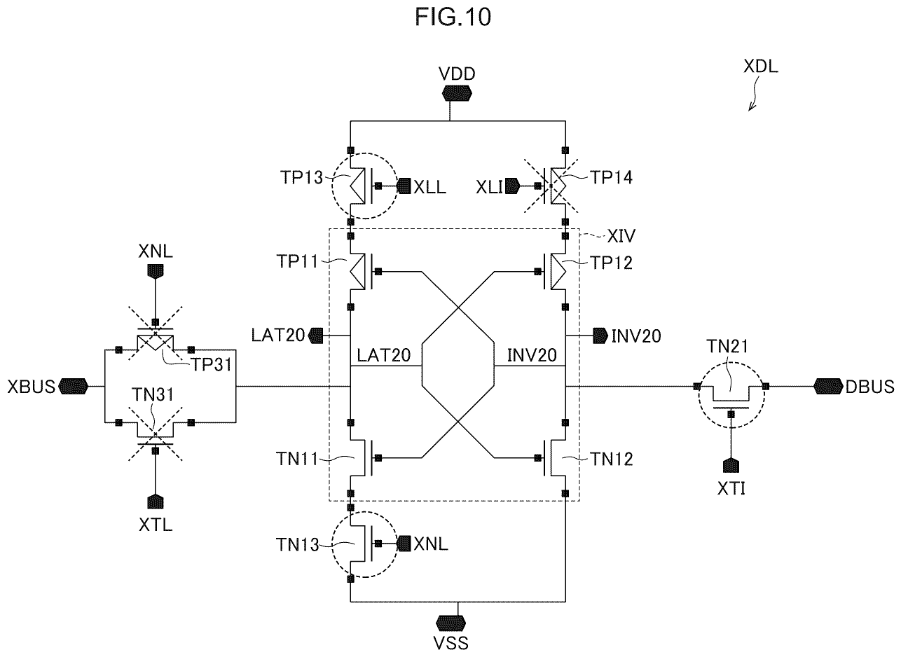

At the start of data input to the data latch circuit XDL from the bus DBUS, the data latch circuit XDL is in the state shown in FIG. 8. During data input to the data latch circuit XDL from the bus DBUS, the sequencer 25 causes the data latch circuit XDL to operate as shown in FIG. 10.

The sequencer 25 keeps the control signal XNL to logic high and the control signal XTL to logic low, and thereby keeps both the transistors TP31 and TN31 off as shown in FIG. 10. Accordingly, the node LAT20 is kept disconnected from the bus XBUS.

By keeping the control signal XLL to logic low, the sequencer 25 keeps the transistor TP13 on. Furthermore, by setting the control signal XLI to logic high, the sequencer 25 turns the transistor TP14 off.

In this state, the sequencer 25 sets the control signal XTI to logic high, and thereby turns on the transistor TN21. Consequently, the node INV20 is connected to the bus DBUS, causing the potential level of the node INV20 to become equal to the potential level of the bus DBUS, and the potential level of the node LAT20 to become opposite the potential level of the bus DBUS. That is, if the potential of the bus DBUS is logic high, the potential of the node INV20 becomes logic high while the level of the node LAT20 becomes logic low. In contrast to this, if the potential of the bus DBUS is logic low, the potential of the node INV20 becomes logic low while the level of the node LAT20 becomes logic high. In this way, the logic low data of the bus DBUS is transferred to the data latch circuit XDL.

After data is transferred to the node INV20 and the node LAT20 as described above, the sequencer 25 sets the control signal XTI to logic low, thereby turning off the transistor TN21. Subsequently, the data latch circuit XDL enters the state shown in FIG. 8, and the data is held in the node INV20 and the node LAT20.

### 1.7.3 Data Output to Bus XBUS

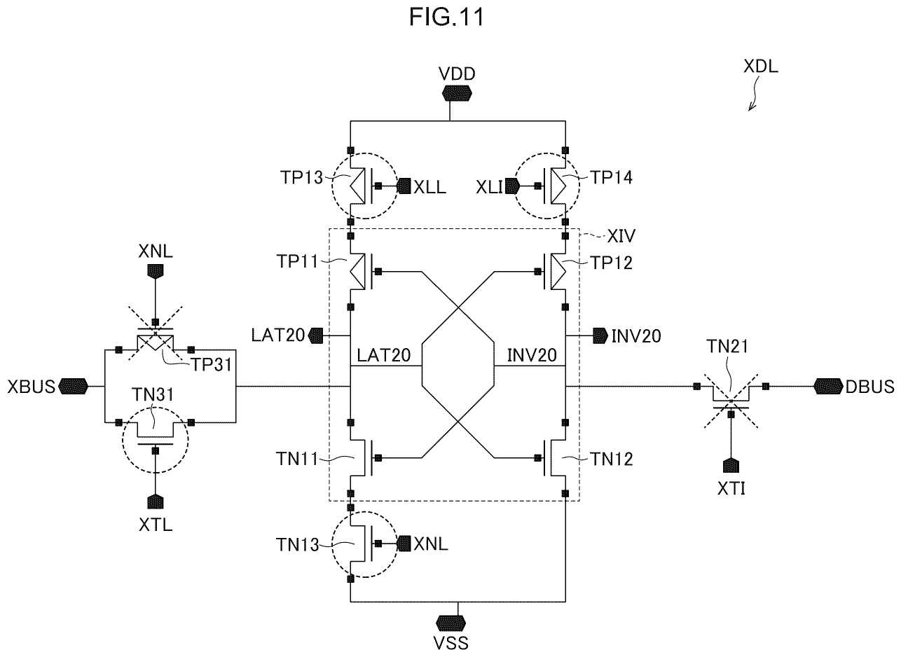

At the start of data output to the bus XBUS, the data latch circuit XDL is in the state shown in FIG. 8. During data output from the data latch circuit XDL to the bus XBUS, the sequencer 25 causes the data latch circuit XDL to operate as shown in FIG. 11.

By keeping the control signal XTI to logic low, the sequencer 25 keeps the transistor TN21 off as shown in FIG. 11. Accordingly, the node INV20 is kept disconnected from the bus DBUS.

Besides the sequencer 25 keeps the control signals XLL and XLI to logic low, and the control signal XNL to logic high, thereby keeping the transistors TP13, TP14, and TN13 on.

In this state, the sequencer 25 sets the control signal XTL to on, thereby turning on the transistor TN31. Consequently, the node LAT20 is connected to the bus XBUS via the transistor TN31, and the level of the node LAT20 is outputted to the bus XBUS. That is, if the potential of the node LAT20 is logic high, the potential of the bus XBUS is set logic high and logic high data is transferred from the data latch circuit XDL to the bus XBUS. On the other hand, if the potential of the node LAT20 is logic low, the potential of the bus XBUS is set logic low and logic low data is transferred from the data latch circuit XDL to the bus XBUS.

### 1.7.4 Data Input from Bus XBUS

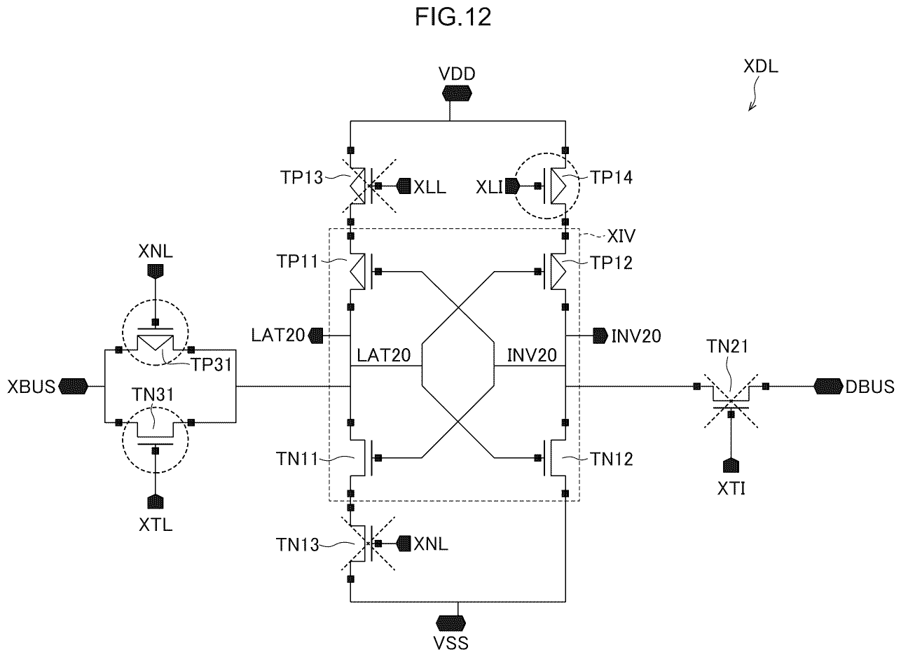

At the start of data input from the bus XBUS, the data latch circuit XDL is in the state shown in FIG. 8 or FIG. 9. During data input to the data latch circuit XDL from the bus XBUS, the sequencer 25 causes the data latch circuit XDL to operate as shown in FIG. 12. That is, the sequencer 25 sets the control signal XNL to logic low, thereby turning on the transistor TP31 and turning off the transistor TN13. Besides, the sequencer 25 sets the control signal XTL to logic high, thereby turning on the transistor TN31. Consequently, the node LAT20 is connected to the bus XBUS, causing the potential level of the node LAT20 to become equal to the potential level of the bus XBUS, and the potential level of the node INV20 to become opposite the potential level of the bus XBUS.

### 1.7.5 Data Output to Bus DBUS

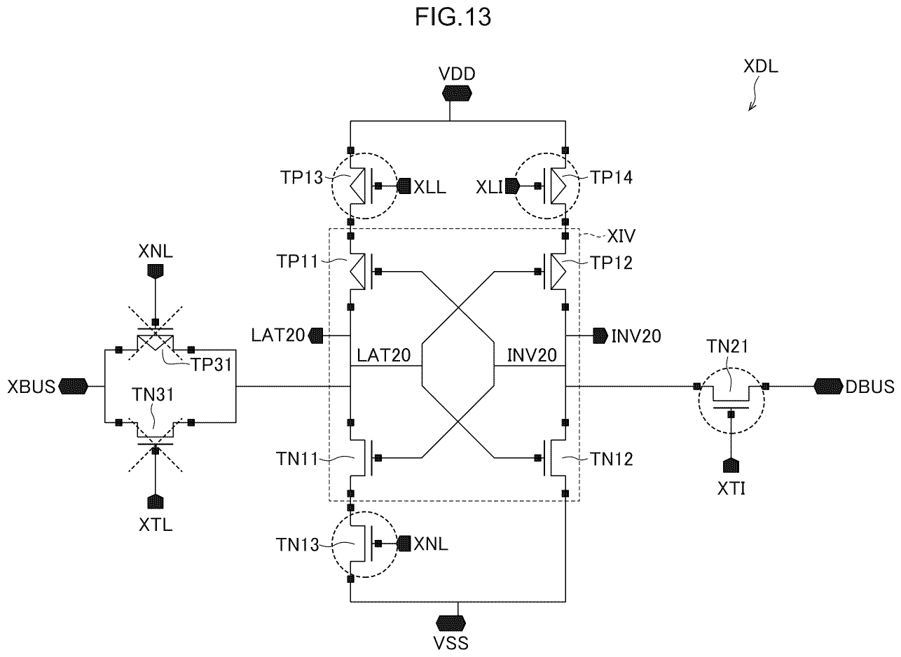

At the start of data output to the bus DBUS, the data latch circuit XDL is in the state shown in FIG. 8 or FIG. 9. During data output from the data latch circuit XDL to the bus DBUS, the sequencer 25 causes the data latch circuit XDL to operate as shown in FIG. 13. Note that the operation of the data latch circuit XDL in doing so is basically the same as the above-mentioned operation of data output from the data latch circuit XDL to the bus XBUS except that the output destination has been changed to the bus DBUS, and thus detailed description thereof will be omitted.

### 1.8 Configuration of Data Latch Circuits SDL, ADL, BDL, CDL, and TDL

Next, the configuration of the data latch circuits SDL, ADL, BDL, CDL, and TDL will be described. Note that since the data latch circuits SDL, ADL, BDL, CDL, and TDL have the same configuration as described above, the configuration of the data latch circuit SDL will be described below representatively.

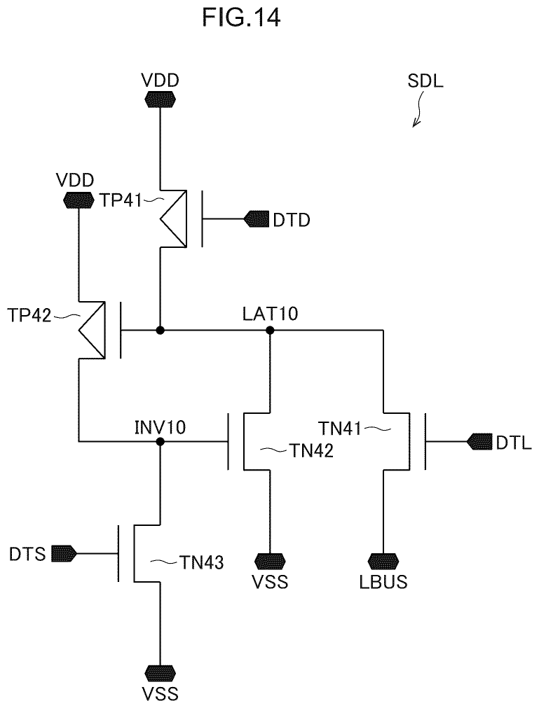

As shown in FIG. 14, the data latch circuit SDL includes enhancement-mode p-channel MOS transistors TP41 and TP42, and enhancement-mode n-channel MOS transistors TN41 to TN43.

A source of the transistor TP41 is connected to the power supply potential node VDD and a drain of the transistor TP41 is connected to a node LAT10. A control signal DTD generated by the sequencer 25 is inputted to a gate of the transistor TP41. The transistor TP41 functions as a switching element that turns on and off based on the control signal DTD.

A source of the transistor TP42 is connected to the power supply potential node VDD and a drain of the transistor TP42 is connected to a node INV10. A gate of the transistor TP42 is connected to the node LAT10.

A source of the transistor TN41 is connected to the bus LBUS and a drain of the transistor TN41 is connected to the node LAT10. A control signal DTL generated by the sequencer 25 is inputted to a gate of the transistor TN41. The transistor TN41 functions as a switching element that turns on and off based on the control signal DTL.

A drain of the transistor TN42 is connected to the node LAT10 and a source of the transistor TN42 is connected to the ground potential node VSS. A gate of the transistor TN42 is connected to the node INV10.

A drain of the transistor TN43 is connected to the node INV10 and a source of the transistor TN43 is connected to the ground potential node VSS. A control signal DTS generated by the sequencer 25 is inputted to a gate of the transistor TN43. The transistor TN43 functions as a switching element that turns on and off based on the control signal DTS.

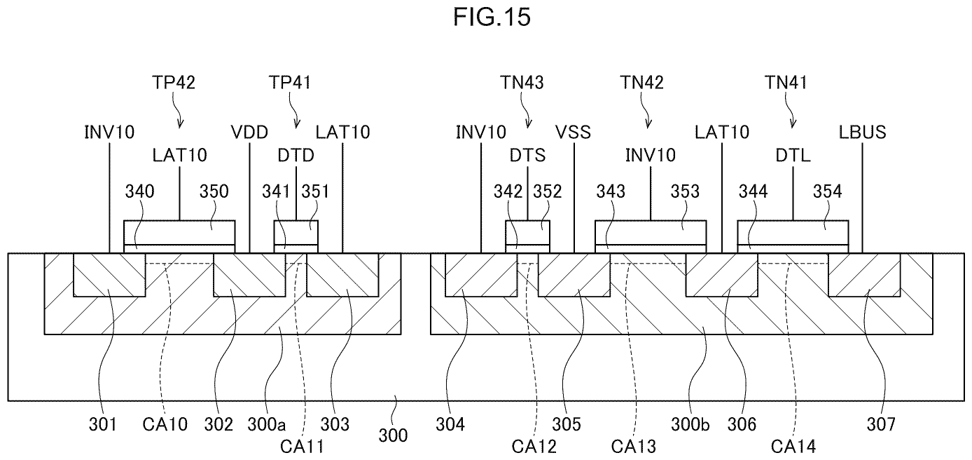

FIG. 15 is a sectional view showing a sectional structure of the semiconductor storage device around the transistors TP41, TP42, and TN41 to TN43.

As shown in FIG. 15, the transistors TP41, TP42, and TN41 to TN43 are formed on a semiconductor substrate 300. The semiconductor substrate 300 is, for example, a p-type silicon substrate. An n-well 300a and a p-well 300b are provided on a surface of the semiconductor substrate 300. The transistors TP41 and TP42, which are p-type MOS transistors, are provided on a surface region of the n-well 300a in the semiconductor substrate 300. The transistors TN41 to TN43, which are n-type MOS transistors, are provided on a surface region of the p-well 300b in the semiconductor substrate 300.

Diffusion layers 301 to 307 containing impurities are formed on the semiconductor substrate 300. The diffusion layer 301 is electrically connected to the node INV10. The diffusion layer 302 is electrically connected to the power supply potential node VDD. The diffusion layer 303 is electrically connected to the node LAT10. The diffusion layer 304 is electrically connected to the node INV10. The diffusion layer 305 is electrically connected to the ground potential node VSS. The diffusion layer 306 is electrically connected to the node LAT10. The diffusion layer 307 is electrically connected to the bus LBUS.

Gate insulators 340 to 344 and gate electrodes 350 to 354 are further provided on the semiconductor substrate 300.

The gate insulator 340 is provided between the diffusion layers 301 and 302 on the semiconductor substrate 300. The gate electrode 350 is provided on the gate insulator 340. The gate electrode 350 is electrically connected with the node LAT10. The diffusion layers 301 and 302 and the gate electrode 350 make up the transistor TP42. The diffusion layer 301 makes up the drain of the transistor TP42 and the diffusion layer 302 makes up the source of the transistor TP42. The part of the semiconductor substrate 300 which is located between the diffusion layers 301 and 302 is where a channel region CA10 of the transistor TP42 is formed.

The gate insulator 341 is provided between the diffusion layers 302 and 303 on the semiconductor substrate 300. The gate electrode 351 is provided on the gate insulator 341. A control signal DTD formed by the sequencer 25 is inputted to the gate electrode 351. The diffusion layers 302 and 303 and the gate electrode 351 make up the transistor TP41. The diffusion layer 302 makes up the source of the transistor TP41 and the diffusion layer 303 makes up the drain of the transistor TP41. The part of the semiconductor substrate 300 which is located between the diffusion layers 302 and 303 is where a channel region CA11 of the transistor TP41 is formed.

The gate insulator 342 is provided between the diffusion layers 304 and 305 on the semiconductor substrate 300. The gate electrode 352 is provided on the gate insulator 342. The control signal DTS formed by the sequencer 25 is inputted to the gate electrode 352. The diffusion layers 304 and 305 and the gate electrode 352 make up the transistor TN43. The diffusion layer 304 makes up the drain of the transistor TN43 and the diffusion layer 305 makes up the source of the transistor TN43. The part of the semiconductor substrate 300 which is located between the diffusion layers 304 and 305 is where a channel region CA12 of the transistor TN43 is formed.

The gate insulator 343 is provided between the diffusion layers 305 and 306 on the semiconductor substrate 300. The gate electrode 353 is provided on the gate insulator 343. The gate electrode 353 is electrically connected with the node INV10. The diffusion layers 305 and 306 and the gate electrode 353 make up the transistor TN42. The diffusion layer 305 makes up the source of the transistor TN42 and the diffusion layer 306 makes up the drain of the transistor TN42. The part of the semiconductor substrate 300 which is located between the diffusion layers 305 and 306 is where a channel region CA13 of the transistor TN42 is formed.

The gate insulator 344 is provided between the diffusion layers 306 and 307 on the semiconductor substrate 300. The gate electrode 354 is provided on the gate insulator 344. A control signal DTL formed by the sequencer 25 is inputted to the gate electrode 354. The diffusion layers 306 and 307 and the gate electrode 354 make up the transistor TN41. The diffusion layer 306 makes up the drain of the transistor TN41 and the diffusion layer 307 makes up the source of the transistor TN41. The part of the semiconductor substrate 300 which is located between the diffusion layers 306 and 307 is where a channel region CA14 of the transistor TN41 is formed.

As shown in FIG. 15, the channel region CA11 of the transistor TP41 and the channel region CA12 of the transistor TN43 are shorter in channel length than the channel region CA10 of the transistor TP42, the channel region CA13 of the transistor TN42, and the channel region CA14 of the transistor TN41. This configuration ensures that no current will flow in the channel regions CA10, CA13, and CA14 when the respective transistors TP42, TN42, and TN41 are off. In contrast to this, when the transistor TP41 and the transistor TN43 are off, leakage currents, which are minute currents corresponding to the drain-source potential differences, can flow in the respective channel regions CA11 and CA12.

### 1.9 Operation Examples of Data Latch Circuit SDL

Next, operation examples of the data latch circuit SDL will be described.

### 1.9.1 Data Retention

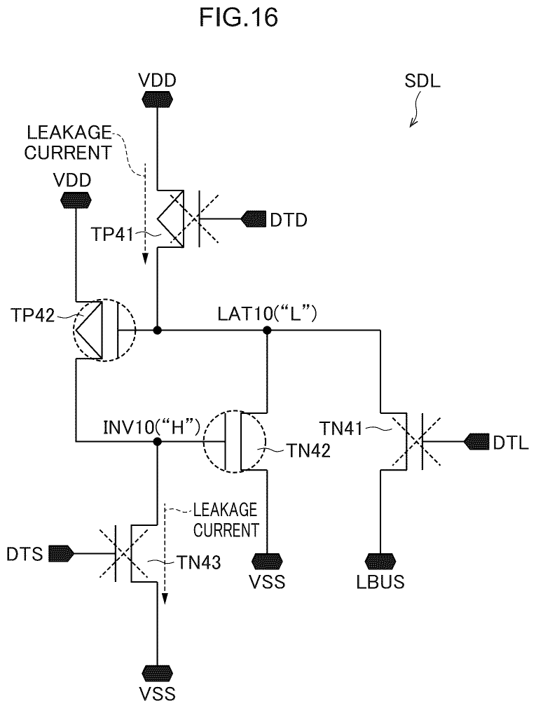

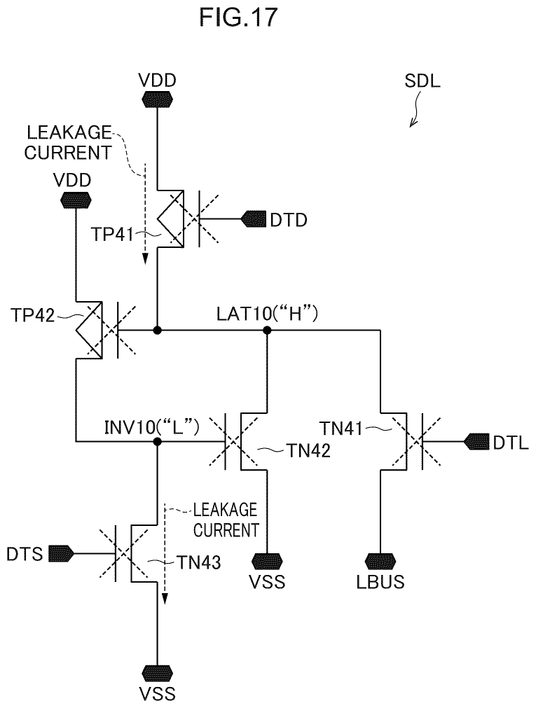

When data is held by the data latch circuit SDL, the sequencer 25 causes the data latch circuit SDL to operate as shown in FIGS. 16 and 17. FIG. 16 is a circuit diagram showing an operation example of the data latch circuit SDL when logic low data is held in the node LAT10 of the data latch circuit SDL. FIG. 17 is a circuit diagram showing an operation example of the data latch circuit SDL when logic high data is held in the node LAT10 of the data latch circuit SDL.

As shown in FIGS. 16 and 17, the sequencer 25 keeps the control signal DTD to logic high and keeps the control signals DTL and DTS to logic low. Consequently, since the transistors TP41, TN41, and TN43 are turned off, both the nodes LAT10 and INV10 are disconnected from the bus LBUS, the power supply potential node VDD, and the ground potential node VSS. Therefore, the respective potentials of the nodes LAT10 and INV10 are maintained. In so doing, the node LAT10 remains logic high or logic low depending on the held data. The node INV10 maintains the logic state opposite the node LAT10.

For example, when logic low data is held in the node LAT10, the transistor TP42 is turned on as shown in FIG. 16, connecting the node INV10 to the power supply potential node VDD via the transistor TP42. Therefore, the node INV10 is set logic high. Consequently, the transistor TN42 turns on, connecting the node LAT10 to the ground potential node VSS via the transistor TN42. Therefore, the node LAT10 remains logic low.

Note that in the state shown in FIG. 16, a leakage current occurs flowing from the power supply potential node VDD toward the node LAT10 via the transistor TP41 remaining off, but since the node LAT10 is connected to the ground potential node VSS, the node LAT10 remains logic low. As a result, in the data latch circuit SDL, logic low data is held in the node LAT10.

Besides, in the state shown in FIG. 16, a leakage current occurs flowing toward the ground potential node VSS via the node INV10 and the transistor TN43 remaining off, but since the node INV10 is connected to the power supply potential node VDD, the node INV10 remains logic high. As a result, in the data latch circuit SDL, logic high data is held in the node INV10.

In this way, in the data latch circuit SDL, when logic low data is held in the node LAT10, logic high data is held in the node INV10.

When logic high data is held in the node LAT10, the transistor TP42 turns off, causing the node INV10 to be disconnected from the power supply potential node VDD. In so doing, a leakage current occurs flowing from the node INV10 toward the ground potential node VSS via the transistor TN43 remaining off, and consequently, the node INV10 changes to logic low over time. As the node INV10 changes to logic low, the transistor TN42 is kept off, thereby keeping the node LAT10 disconnected from the ground potential node VSS. In so doing, a leakage current occurs flowing from the power supply potential node VDD toward the node LAT10 via the transistor TP41 remaining off, and consequently, the node LAT10 remains logic high. As a result, in the data latch circuit SDL, logic high data is held in the node LAT10.

In this way, in the data latch circuit SDL, when logic high data is held in the node LAT10, logic low data is held in the node INV10.

### 1.9.2 Data Input from Bus LBUS

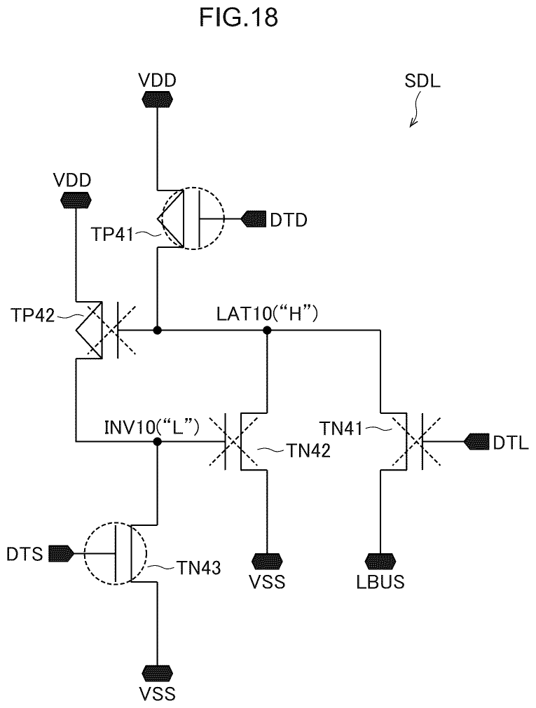

When inputting data to the data latch circuit SDL from the bus LBUS, the sequencer 25 causes the data latch circuit SDL to operate as shown in FIGS. 18 to 20.

Specifically, before starting data input to the data latch circuit SDL from the bus LBUS, the sequencer 25 operates the data latch circuit SDL as shown in FIG. 18 to reset the logic levels of the nodes LAT10 and INV10. That is, the sequencer 25 sets the control signals DTL and DTD to logic low, and the control signal DTS to logic high. Consequently, the transistors TP41 and TN43 turn on, and the transistor TN41 turns off. Therefore, the node LAT10 becomes disconnected from the bus LBUS, but connected to the power supply potential node VDD. Accordingly, the node LAT10 is set logic high.

As the node LAT10 is set logic high, the transistor TP42 turns off. The node INV10 is connected to the ground potential node VSS via the transistor TN43 remaining on. Therefore, the node INV10 is set logic low. As the node INV10 is set logic low, the transistor TN42 is turned off, setting the node LAT10 to logic high.

In this way, as a result of a reset operation, the node LAT10 is set logic high and the node INV10 is set logic low.

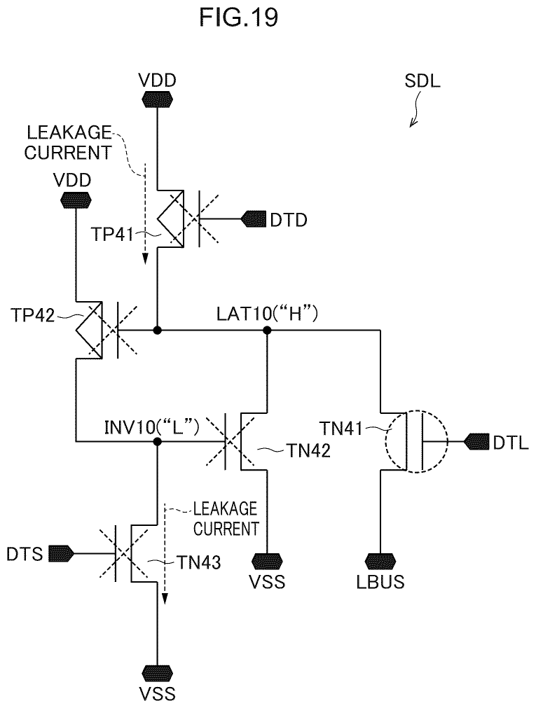

Following the reset operation, the sequencer 25 operates the data latch circuit SDL as shown in FIG. 19 to input data to the data latch circuit SDL from the bus LBUS. That is, the sequencer 25 sets the control signals DTL and DTD to logic high, and the control signal DTS to logic low. Consequently, the transistor TN41 turns on, and the transistors TP41 and TN43 turn off. In so doing, depending on whether the data inputted to the data latch circuit SDL from the bus LBUS is logic high data or logic low data, the data latch circuit SDL operates as follows.

If the data inputted to the data latch circuit SDL from the bus LBUS is logic high data the node LAT10 remains logic high. That is, since the state of the data latch circuit SDL remains as shown in FIG. 19, the node LAT10 remains logic high and the node INV10 remains logic low. As a result, logic high data is inputted to the node LAT10 and logic low data is inputted to the node INV10.

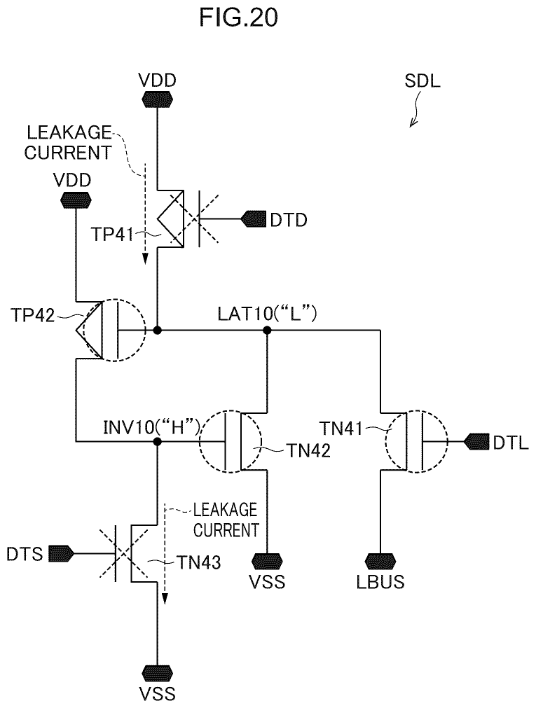

On the other hand, if the data inputted to the data latch circuit SDL from the bus LBUS is logic low data, the node LAT10 changes from logic high to logic low. Consequently, as shown in FIG. 20, the transistor TP42 turns on, connecting the node INV10 to the power supply potential node VDD via the transistor TP42. Consequently, the node INV10 changes from logic low to logic high. As a result, logic low data is inputted to the node LAT10 and logic high data is inputted to the node INV10.

After data is inputted to the node LAT10 in this way, the sequencer 25 sets the control signal DTL to logic low and thereby turns off the transistor TN41. Consequently, when logic high data is inputted to the node LAT10, the data latch circuit SDL changes from the state shown in FIG. 19 to the state shown in FIG. 17, causing the node LAT10 to hold logic high data, and the node INV10 to hold logic low data. On the other hand, when logic low data is inputted to the node LAT10, the data latch circuit SDL changes from the state shown in FIG. 20 to the state shown in FIG. 16, causing the node LAT10 to hold logic low data, and the node INV10 to hold logic high data.

### 1.9.3 Data Output to Bus LBUS

At the start of data output to the bus LBUS, when logic low data is held in the node LAT10, the data latch circuit SDL is in the state shown in FIG. 16, and when logic high data is held in the node LAT10, the data latch circuit SDL is in the state shown in FIG. 17. In the case of data output to the bus LBUS from the data latch circuit SDL, the sequencer 25 sets the control signal DTL to on in the state shown in FIG. 16 or 17. Consequently, if the data latch circuit SDL is in the state shown in FIG. 16, i.e., if logic low data is held in the node LAT10, the transistor TN41 turns on, thereby causing logic low data to be outputted to the bus LBUS. On the other hand, if the data latch circuit SDL is in the state shown in FIG. 17, i.e., if logic high data is held in the node LAT10, the transistor TN41 turns on, thereby causing logic high data to be outputted to the bus LBUS.

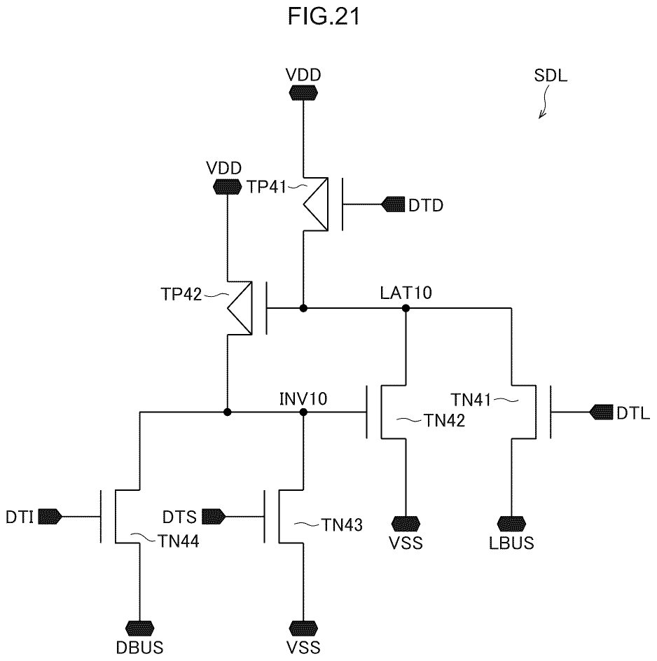

Note that in order to output data held in the node INV10 to the bus LBUS, the data latch circuit SDL may have a configuration such as shown in FIG. 21. The data latch circuit SDL shown in FIG. 21 further includes an enhancement-mode n-channel MOS transistor TN44. A drain of the transistor TN44 is connected to the node INV10 and a source of the transistor TN44 is connected to the bus LBUS. A control signal DTI generated by the sequencer 25 is inputted to a gate of the transistor TN44. The transistor TN44 functions as a switching element that turns on and off based on the control signal DTI.

When data is held in the data latch circuit SDL and when data is inputted to the data latch circuit SDL from the bus LBUS, the sequencer 25 sets the control signal DTI to off and thereby keeps the transistor TN44 off.

To output the data held in the node INV10 to the bus LBUS, the sequencer 25 sets the control signal DTL to off and sets the control signal DTI to on. Consequently, the data held in the node INV10 is outputted to the bus LBUS via the transistor TN44.

### 1.10 Actions and Effects of Embodiment

As shown in FIG. 14, the data latch circuit SDL according to the present embodiment includes the transistor TN41 (a first transistor), the transistor TP41 (a second transistor), the transistor TN42 (a third transistor), the transistor TP42 (a fourth transistor), and the transistor TN43 (a fifth transistor). A current path of the transistor TN41 is connected to the node LAT10 (a first node) at one end, and to the bus LBUS (a first bus) at another end. A current path of the transistor TP41 is connected at one end to the power supply potential node VDD (a first potential node) having a potential (a first potential) corresponding to the power supply voltage Vdd, and connected at another end to the node LAT10. A current path of the transistor TN42 is connected at one end to the node LAT10 and connected at another end to the ground potential node VSS (a second potential node) having a potential (a second potential) corresponding to the ground voltage Vss lower than the power supply voltage Vdd. The gate of the transistor TN42 is connected to the node INV10 (a second node). A current path of the transistor TP42 is connected to the power supply potential node VDD at one end, and to the node INV10 at another end. A gate of the transistor TP42 is connected to the node LAT10. A current path of the transistor TN43 is connected to the node INV10 at one end and to the ground potential node VSS at another end. When the transistor TP41 is off, a leakage current corresponding to a potential difference between the power supply potential node VDD and the node LAT10 will occur in the transistor TP41. When the transistor TN43 is off, a leakage current corresponding to a potential difference between the node INV10 and the ground potential node VSS will occur in the transistor TN43.

This configuration makes it possible to reduce the number of transistors compared to when the data latch circuit SDL uses a cross-connected inverter circuit XIV in which input and output are cross-connected such as shown in FIG. 7. This in turn makes it possible to reduce chip size.

The transistor TP41 and the transistor TP42 are enhancement-mode p-channel MOS transistors. The transistor TP41 is shorter in channel length than the transistor TP42. The transistor TN41, the transistor TN42, and the transistor TN43 are enhancement-mode n-channel MOS transistors. The transistor TN43 is shorter in channel length than the transistor TN41 and the transistor TN42.

This configuration makes it possible to easily generate leakage currents in the transistors TP42 and TN43.

The semiconductor storage device 2 includes the sequencer 25 (a control unit) configured to control the data latch circuit SDL (a first data latch circuit). Before inputting data to at least one of the node LAT10 and node INV10, the sequencer 25 connects the node LAT10 to the power supply potential node VDD, and the node INV10 to the ground potential node VSS by turning on the transistor TP41 and the transistor TN43 with the transistor TN41 turned off as shown in FIG. 18.

This configuration makes it possible to reset the logic levels of the nodes LAT10 and INV10 before inputting data to at least one of the node LAT10 and node INV10.

When inputting data to at least one of the node LAT10 and node INV10, the sequencer 25 turns on the transistor TN41 with the transistor TP41 and the transistor TN43 turned off as shown in FIGS. 19 and 20.

This configuration makes it possible to input data to the node LAT10 and the node INV10 from the bus LBUS.

When holding data to at least one of the node LAT10 and node INV10, the sequencer 25 turns off the transistor TN41, the transistor TP41, and the transistor TN43 as shown in FIGS. 16 and 17.

This configuration makes it possible to hold logic high data or logic low data in the node LAT10. The configuration also allows the data from the node LAT10 to be held in the node INV10 after bit inversion.

The semiconductor storage device 2 further includes the transistor TN44 (sixth transistor) as shown in FIG. 21. The transistor TN44 is connected to the node INV10 at one end, and to the bus LBUS at another end.

This configuration makes it possible to output the data held in the node INV10 to the bus LBUS.

In the semiconductor storage device 2, the data latch circuit SDL is connected to the sense amplification parts SA. The semiconductor storage device 2 further includes the data latch circuit XDL (a second data latch circuit XDL). The data latch circuit XDL is connected to the data latch circuit SDL via the bus LBUS (the first bus), and to the input-output circuit 22 via the bus XBUS (a second bus). The data latch circuit XDL is different in configuration from the data latch circuit SDL. Specifically, the data latch circuit XDL includes the cross-connected inverter circuit XIV.

This configuration makes it possible to reduce the number of transistors and thereby reduce the chip size in the data latch circuit SDL while implementing faster operation in the data latch circuit XDL.

### 1.11 First modification

Next, a first modification of the semiconductor storage device 2 and data latch circuit SDL according to the embodiment will be described.

Whereas in the semiconductor storage device 2 according to the above embodiment, to generate leakage currents in the transistors TN43 and TP41, the transistors TN43 and TP41 are set shorter in channel length than the other transistors TN41, TN42, and TP42, another method may be adopted to generate leakage currents in the transistors TN43 and TP41.

For example, while using an enhancement-mode p-channel MOS transistor for the transistor TP42, a depletion-mode p-channel MOS transistor may be used for the transistor TP41. Similarly, while using enhancement-mode n-channel MOS transistors for the transistors TN41 and TN42, a depletion-mode n-channel MOS transistor may be used for the transistor TN43. In that case, the transistors TP41 and TN43 do not have to be shorter in channel length than the other transistors TP42, TN41, and TN42. Even with such a configuration, actions and effects the same as or similar to the semiconductor storage device 2 and data latch circuit SDL according to the above embodiment are available.

### 1.12 Second modification

Next, a second modification of the semiconductor storage device 2 and data latch circuit SDL according to the embodiment will be described.

Whereas the semiconductor storage device 2 according to the above embodiment adopts a configuration that uses the transistor TN44 as shown in FIG. 21 to output the data held in the node INV10 to the bus LBUS, the configuration may be changed as appropriate.

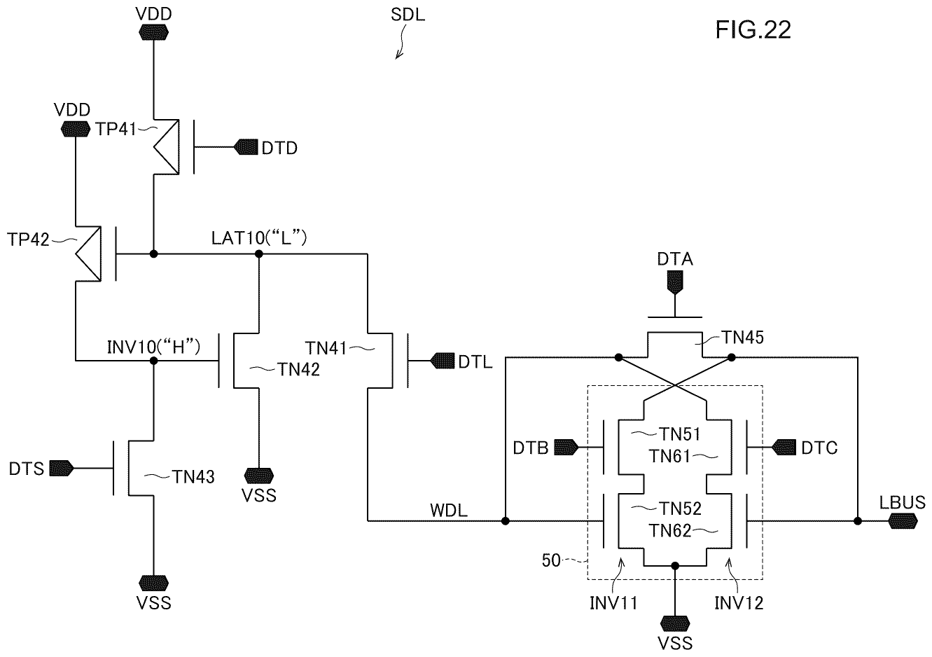

For example, as shown in FIG. 22, in the semiconductor storage device 2 according to the present modification, the transistor TN41 has its drain connected to the node LAT10, and has its source connected to a line WDL. The semiconductor storage device 2 further includes a transistor TN45 and an inverter 50 connected to the line WDL.

The transistor TN45 is an enhancement-mode n-channel MOS transistor. A drain of the transistor TN45 is connected to the bus LBUS, and a source of the transistor TN45 is connected the line WDL. A control signal DTA generated by the sequencer 25 is inputted to a gate of the transistor TN45. The transistor TN45 functions as a switching element that turns on and off based on the control signal DTA.

The inverter 50 is a circuit used to output data held in the node LAT10 to the bus LBUS after bit inversion. The inverter 50 includes inverter circuits INV11 and INV12.

The inverter circuit INV11 is made up of transistors TN51 and TN52 connected in series. A drain of the topside transistor TN51 is connected to the bus LBUS. A source of the underside transistor TN52 is connected to the ground potential node VSS. A control signal DTB generated by the sequencer 25 is inputted to a gate of the topside transistor TN51. The topside transistor TN51 functions as a switching element that turns on and off based on the control signal DTB. A gate of the underside transistor TN52 is connected with the line WDL.

The inverter circuit INV12 is made up of transistors TN61 and TN62 connected in series. A drain of the topside transistor TN61 is connected to the line WDL. A source of the underside transistor TN62 is connected to the ground potential node VSS. A control signal DTC generated by the sequencer 25 is inputted to a gate of the topside transistor TN61. The topside transistor TN61 functions as a switching element that turns on and off based on the control signal DTC. A gate of the underside transistor TN62 is connected with the bus LBUS.

Note that the transistor TN45 and the inverter circuits INV11 and INV12 may be either included in the data latch circuit SDL or provided separately from the data latch circuit SDL.

Next, operation examples of the semiconductor storage device 2 according to the present embodiment will be described.

To output the data held in the node LAT10 of the data latch circuit SDL as it is to the bus LBUS, the sequencer 25 operates the semiconductor storage device 2 as follows.

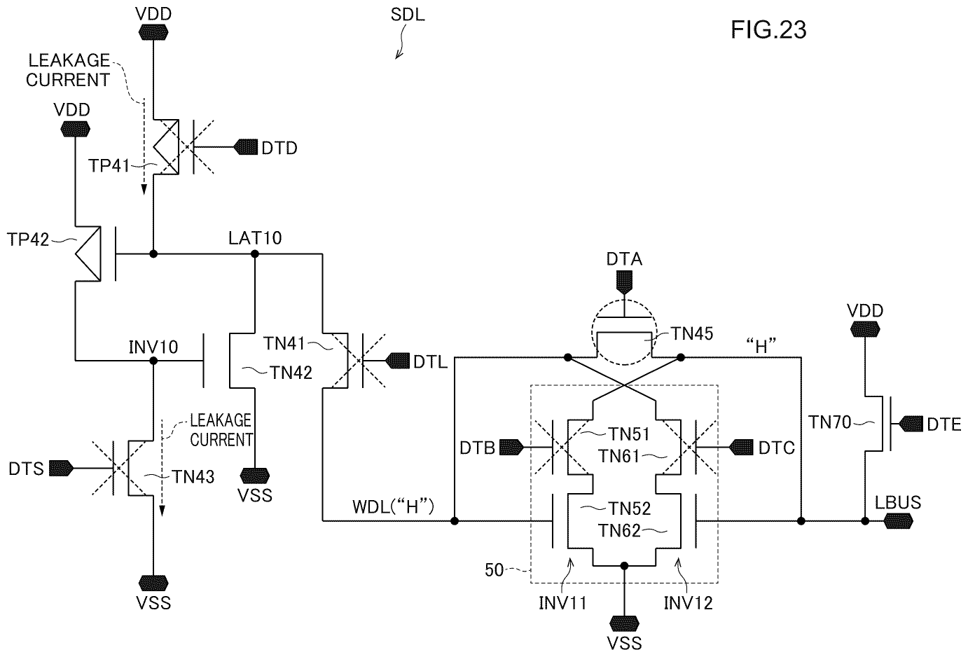

First, before data output to the bus LBUS, the sequencer 25 performs a reset process to reset the respective logic levels of the line WDL and the bus LBUS. Specifically, the sequencer 25 sets the control signals DTL, DTS, DTB, DTC to logic low, and the control signal DTD to logic high. Consequently, as shown in FIG. 23, the transistors TP41, TN41, TN43, TN51, and TN61 are all turned off. The bus LBUS is connected with a source of a transistor TN70. A drain of the transistor TN70 is connected to the power supply potential node VDD. The transistor TN70 is a charging transistor for use to supply the power supply voltage Vdd to the bus LBUS. A control signal DTE generated by the sequencer 25 is inputted to a gate of the transistor TN70. When the transistors TP41, TN41, TN43, TN51, and TN61 are all off as shown in FIG. 23, the sequencer 25 sets the control signals DTA and DTE to logic high. Consequently, as the transistors TN45 and TN70 are both turned on, the line WDL and the bus LBUS are connected to the power supply potential node VDD. Thus, both the line WDL and the bus LBUS are set logic high. Note that in FIGS. 22 and 24 to 26, illustration of the transistor TN70 is omitted. When outputting the data held in the data latch circuit SDL to the bus LBUS, the sequencer 25 keeps the control signal DTE to logic low, and thereby keeps the transistor TN70 off.

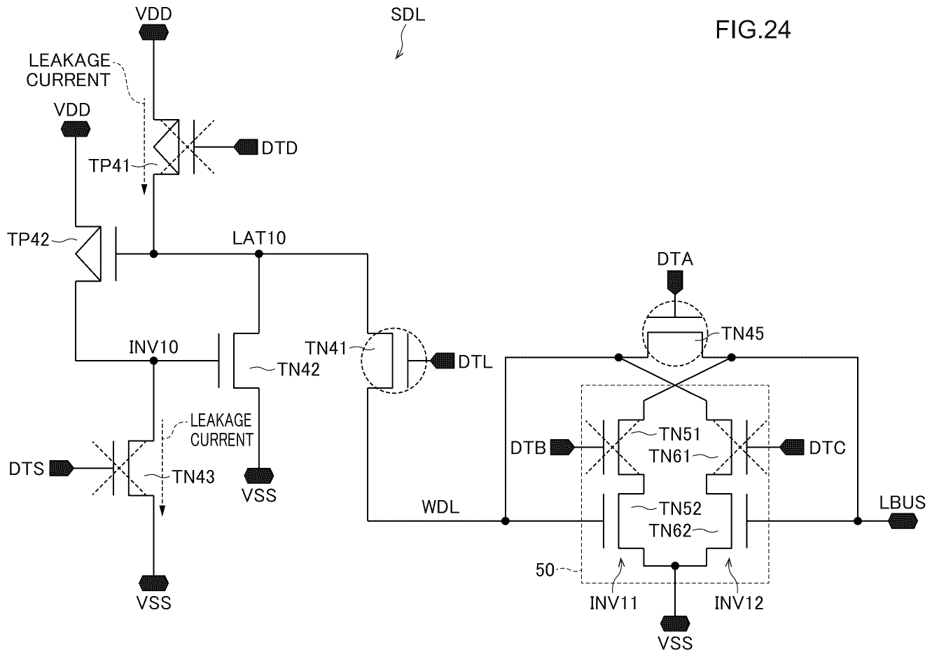

Following the reset process, to output the data held in the node LAT10 to the bus LBUS, the sequencer 25 operates the data latch circuit SDL, the transistor TN45, and the inverter circuits INV11 and INV12 as shown in FIG. 24.

Specifically, the sequencer 25 sets the control signals DTL and DTA to logic high. Consequently, as shown in FIG. 24, the transistors TN41 and TN45 turn on. In so doing, if logic high data is held in the node LAT10, as the transistors TN41 and TN45 turn on, the logic high data held in the node LAT10 is outputted to the bus LBUS via the transistor TN41, the line WDL, and the transistor TN45. When logic low data is held in the node LAT10, similarly, the logic low data held in the node LAT10 is also outputted to the bus LBUS via the transistor TN41, the line WDL, and the transistor TN45.

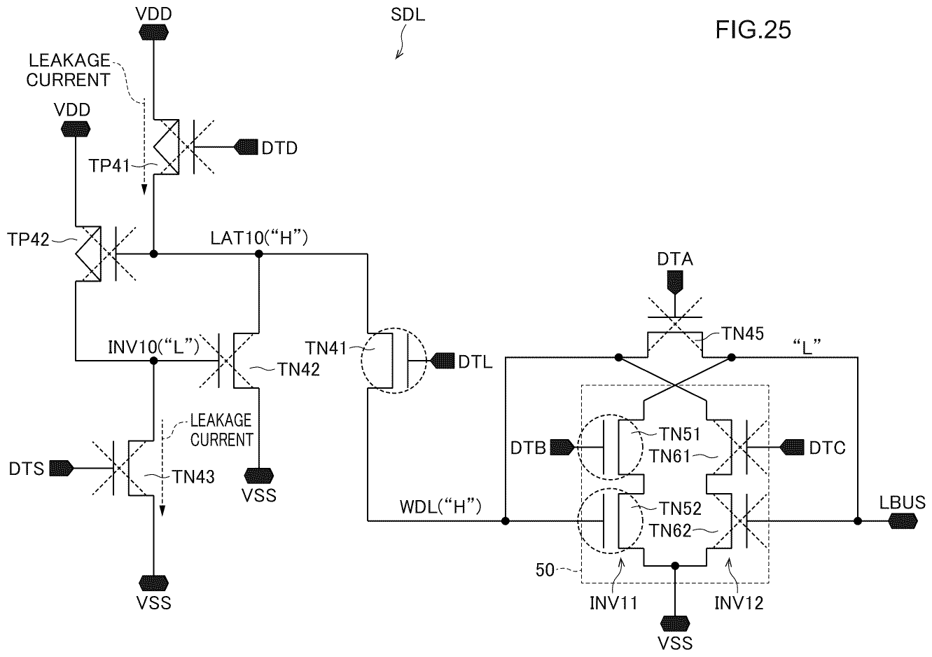

On the other hand, to output the data held in the node INV10 after bit inversion, in other words, to output the data held in the node INV10, to the bus LBUS, the sequencer 25 operates the data latch circuit SDL, the transistor TN45, and the inverter circuits INV11 and INV12 as shown in FIG. 25.

Specifically, the sequencer 25 sets the control signals DTL and DTB to logic high. Consequently, as shown in FIG. 25, the transistors TN41 and TN51 turn on. In so doing, if logic high data is held in the node LAT10, as the transistor TN41 turns on, the logic high data held in the node LAT10 is outputted to the line WDL via the transistor TN41. Consequently, the transistor TN52 turns on, connecting the bus LBUS to the ground potential node VSS via the transistors TN51 and TN52. Thus, the potential of the bus LBUS changes to logic low. As a result, the data obtained by bit-inverting the logic high data held in the node LAT10 can be outputted to the bus LBUS.

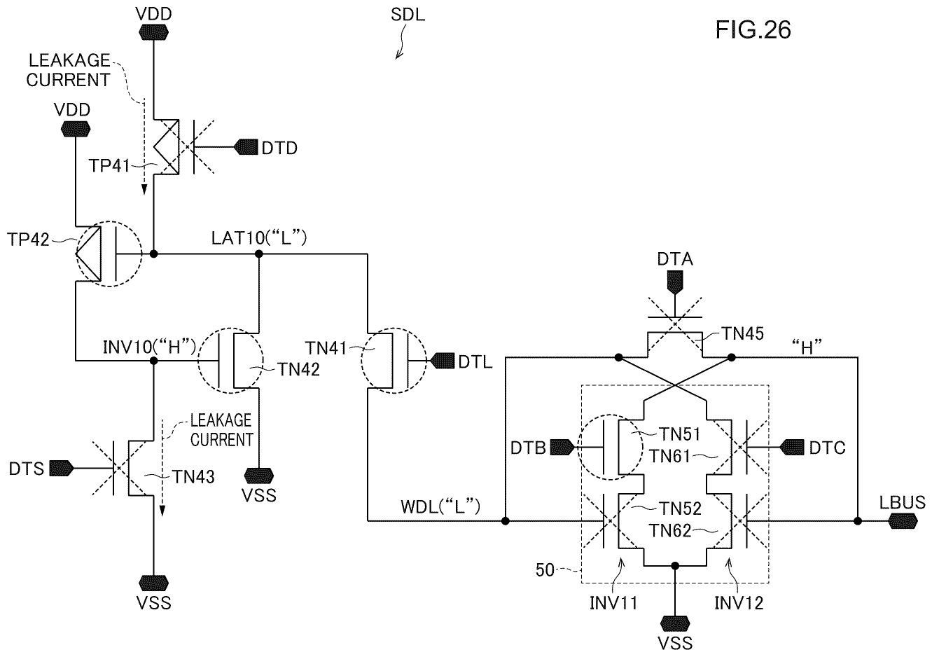

On the other hand, if logic low data is held in the node LAT10, as the transistor TN41 turns on, the logic low data held in the node LAT10 is outputted to the line WDL via the transistor TN41. Consequently, as shown in FIG. 26, the transistor TN52 is kept off, keeping the bus LBUS from being connected to the ground potential node VSS. That is, the potential of the bus LBUS is kept at the post-reset level, specifically, at logic high. As a result, logic high data obtained by bit-inverting the logic low data held in the node LAT10 can be outputted to the bus LBUS.

### 2 Other Embodiments

The present disclosure is not limited to the concrete examples described above.

For example, the data latch circuits SDL according to the above embodiment and modifications can be adopted not only in the semiconductor storage device 2, but also in any semiconductor storage device. The data latch circuits SDL according to the above embodiment and modifications can also be adopted in any device other than semiconductor devices.

The data latch circuit XDL may have a structure identical to that of the data latch circuits SDL.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A data latch circuit comprising:
a first transistor, a current path of which is connected at one end to a first node, and connected at another end to a first bus;
a second transistor, a current path of which is connected at one end to a first potential node having a first potential, and connected at another end to the first node;
a third transistor, a current path of which is connected at one end to the first node, and connected at another end to a second potential node having a second potential lower than the first potential, a gate of the third transistor being connected to a second node;
a fourth transistor, a current path of which is connected at one end to the first potential node, and connected at another end to the second node, a gate of the fourth transistor being connected to the first node; and
a fifth transistor, a current path of which is connected at one end to the second node, and connected at another end to the second potential node,
wherein when the second transistor is off, a leakage current corresponding to a potential difference between the first potential node and the first node occurs in the second transistor, and
when the fifth transistor is off, a leakage current corresponding to a potential difference between the second node and the second potential node occurs in the fifth transistor.

2. The data latch circuit according to claim 1, wherein:
the second transistor and the fourth transistor are enhancement-mode p-channel MOS transistors; and
the second transistor is shorter in channel length than the fourth transistor.

3. The data latch circuit according to claim 1, wherein:
the second transistor is a depletion-mode p-channel MOS transistor; and
the fourth transistor is an enhancement-mode p-channel MOS transistor.

4. The data latch circuit according to claim 1, wherein:
the first transistor, the third transistor, and the fifth transistor are enhancement-mode transistors; and
the fifth transistor is shorter in channel length than the first transistor and the third transistor.

5. The data latch circuit according to claim 1, wherein:
the first transistor and the third transistor are enhancement-mode n-channel MOS transistors;
the fifth transistor is a depletion-mode n-channel MOS transistor.

6. A semiconductor device comprising:
a first data latch circuit configured to hold data in at least one of a first node and a second node; and
a control unit configured to control the first data latch circuit, wherein the first data latch circuit includes;
a first transistor, a current path of which is connected at one end to the first node, and connected at another end to a first bus,
a second transistor, a current path of which is connected at one end to a first potential node having a first potential, and connected at another end to the first node,
a third transistor, a current path of which is connected at one end to the first node, and connected at another end to a second potential node having a second potential lower than the first potential, a gate of the third transistor being connected to the second node,
a fourth transistor, a current path of which is connected at one end to the first potential node, and connected at another end to the second node, a gate of the fourth transistor being connected to the first node, and
a fifth transistor, a current path of which is connected at one end to the second node, and connected at another end to the second potential node, and
when the second transistor is off, a leakage current corresponding to a potential difference between the first potential node and the first node occurs in the second transistor, and
when the fifth transistor is off, a leakage current corresponding to a potential difference between the second node and the second potential node occurs in the fifth transistor.

7. The semiconductor device according to claim 6, wherein before inputting data to the first node from the first bus via the first transistor, the control unit turns on the second transistor and the fifth transistor with the first transistor turned off, thereby connecting the first node to the first potential node and connecting the second node to the second potential node.

8. The semiconductor device according to claim 6, wherein when inputting data to the first node from the first bus via the first transistor, the control unit turns on the first transistor with the second transistor and the fifth transistor turned off.

9. The semiconductor device according to claim 6, wherein when holding data in at least one of the first node and the second node, the control unit turns off the first transistor, the second transistor, and the fifth transistor.

10. The semiconductor device according to claim 6, further comprising an inverter connected to the first bus and configured to bit-invert data held in the first node.

11. The semiconductor device according to claim 6, further comprising a sixth transistor, a current path of which is connected at one end to the second node, and connected at another end to the first bus.

12. The semiconductor device according to claim 6, wherein:
the first data latch circuit is connected to a sense amplification part via the first bus;
the semiconductor device further comprises a second data latch circuit connected to the first data latch circuit via the first bus and connected to an input-output circuit via a second bus; and
the second data latch circuit is different in configuration from the first data latch circuit.

13. The semiconductor device according to claim 12, wherein the second data latch circuit includes an inverter circuit, input and output of which are cross-connected.

14. The semiconductor device according to claim 6, further comprising:
an input/output pad;
a memory cell array containing a plurality of memory cells configured to store data; and
an input-output circuit configured to input and output data between the input/output pad and the memory cell array via the first data latch circuit.

15. The semiconductor device according to claim 14, wherein the input-output circuit is compliant with toggle DDR standard.

16. The semiconductor device according to claim 14, wherein the input-output circuit is compliant with the ONFI standard.
